(19) United States
(12) Patent Application Publication
(10) Pub. No.: US 2025/0133938 A1
(43) Pub. Date: Apr. 24, 2025

(54) DISPLAY DEVICE

(71) Applicant: Samsung Display Co., Ltd., Yongin-si (KR)

(72) Inventor: YUK-HYUN NAM, Yongin-si (KR)

(73) Assignee: Samsung Display Co., Ltd., Yongin-si (KR)

(21) Appl. No.: 18/820,798

(22) Filed: Aug. 30, 2024

(30) Foreign Application Priority Data
Oct. 18, 2023 (KR) 10-2023-0139423

(51) Int. Cl. H10K 59/80; H10K 59/126; H10K 59/38; H10K 59/70; H10K 102/00

(52) U.S. Cl. CPC H10K 59/877; H10K 59/126; H10K 59/38; H10K 59/70; H10K 2102/351

(57) ABSTRACT

A display device includes a base layer, a circuit layer disposed on the base layer, a display element layer disposed on the circuit layer, and including a light-emitting element, and an optical layer disposed on the display element layer. The light-emitting element includes a first light-emitting element overlapping a first light-emitting region, and including a first light-emitting layer, a second light-emitting element overlapping a second light-emitting region, and including a second light-emitting layer, and a third light-emitting element overlapping a third light-emitting region, and including a third light-emitting layer, the first and second light-emitting layers respectively include a first and second quantum dots, and the third light-emitting layer includes an organic light-emitting material, and the optical layer includes a first color filter overlapping the first light-emitting region, a second color filter overlapping the second light-emitting region, and a third color filter overlapping the third light-emitting region, and including scattering particles.

### CROSS-REFERENCE TO RELATED APPLICATIONS

This U.S. non-provisional patent application claims priority to and the benefit of Korean Patent Application No. 10-2023-0139423 under 35 U.S.C. § 119, filed on Oct. 18, 2023, the entire contents of which are hereby incorporated by reference.

### BACKGROUND

### 1. Technical Field

The present disclosure herein relates to a display device, and particularly, to a display device with improved light-emitting characteristics and reliability.

### 2. Description of the Related Art

Various display devices, used for a multimedia device, such as a television, a smartphone, a tablet computer, a navigation system, or a game console are being developed. These display devices use a so-called self-luminous display element that achieves display by emitting light from a light-emitting material containing an organic compound.

In addition, in order to improve color reproducibility of the display devices, development of a light-emitting element using a quantum dot as the light-emitting material is in progress, and there is a demand for improving a lifespan and light-emitting efficiency of the light-emitting element using the quantum dot.

### SUMMARY

The present disclosure provides a display device with improved light-emitting characteristics and color reproducibility.

An embodiment provides a display device including a base layer, a circuit layer disposed on the base layer, a display element layer disposed on the circuit layer, and including a light-emitting element, and an optical layer disposed on the display element layer, wherein the light-emitting element includes a first light-emitting element overlapping a first light-emitting region, and including a first light-emitting layer, a second light-emitting element overlapping a second light-emitting region, and including a second light-emitting layer, and a third light-emitting element overlapping a third light-emitting region, and including a third light-emitting layer, the first light-emitting layer and the second light-emitting layer respectively include a first quantum dot and a second quantum dot, and the third light-emitting layer includes an organic light-emitting material, and the optical layer includes a first color filter overlapping the first light-emitting region, a second color filter overlapping the second light-emitting region, and a third color filter overlapping the third light-emitting region, and including scattering particles.

In an embodiment, the scattering particles may include at least one of zinc oxide, titanium oxide, and silicon oxide.

In an embodiment, the third color filter may include a scattering portion disposed on the display element layer, and including the scattering particles, and a filter portion disposed on the scattering portion, and including a colorant.

In an embodiment, the scattering portion may further include a polymer photosensitive resin, and the scattering particles may be distributed in the polymer photosensitive resin.

In an embodiment, the display element layer may further include an encapsulation layer covering the light-emitting element, and the scattering portion may be in contact with the encapsulation layer.

In an embodiment, the filter portion may be directly disposed on the scattering portion.

In an embodiment, the scattering portion may have a thickness in a range of about 1 μm to about 4 μm.

In an embodiment, the first color filter may include a red pigment or dye, the second color filter may include a green pigment or dye, and the colorant included in the filter portion may include a blue pigment or dye.

In an embodiment, the optical layer may further include light-blocking portions respectively disposed between the first color filter, the second color filter, and the third color filter.

In an embodiment, the optical layer may further include an overcoat layer disposed on the first to third color filters.

In an embodiment, the first to third light-emitting elements may respectively generate first to third light, and the third light may be blue color light having a central wavelength in a range of about 420 nm to about 480 nm.

In an embodiment, the first light-emitting layer may include a first host and a first dopant, the second light-emitting layer may include a second host and a second dopant, the first dopant may include the first quantum dot, and the second dopant may include the second quantum dot.

In an embodiment, the third light-emitting layer may include a third host and a third dopant, and the third host and the third dopant may each include the organic light-emitting material.

In an embodiment, the third dopant may include a delayed fluorescent dopant.

In an embodiment, the light-emitting element may include a first electrode, a light-emitting layer disposed on the first electrode, and a second electrode disposed on the light-emitting layer, and the light-emitting layer may include the first light-emitting layer, the second light-emitting layer, and the third light-emitting layer.

In an embodiment, the light-emitting element may further include a capping layer disposed on the second electrode.

In an embodiment, the first light-emitting element may further include a first electron transport region disposed on the first light-emitting layer, the second light-emitting element may further include a second electron transport region disposed on the second light-emitting layer, and the first electron transport region and the second electron transport region may each include an inorganic material.

In an embodiment, the third light-emitting element may further include a third electron transport region disposed on the third light-emitting layer, and the third electron transport region may include an organic material.

In an embodiment, the third light-emitting layer may include a (3-1)-th light-emitting layer disposed on the first electrode, and a (3-2)-th light-emitting layer disposed on the (3-1)-th light-emitting layer, and the third light-emitting element may further include a charge generation layer disposed between the (3-1)-th light-emitting layer and the (3-2)-th light-emitting layer.

In an embodiment, a display device includes a base layer, a circuit layer disposed on the base layer, a display element layer disposed on the circuit layer, and including a light-emitting element, and an optical layer disposed on the display element layer, wherein the light-emitting element includes an organic light-emitting material, and the optical layer includes a scattering portion including titanium dioxide (TiO₂), and a filter portion directly disposed on the scattering portion, and including a pigment or dye.

### BRIEF DESCRIPTION OF THE DRAWINGS

The accompanying drawings are included to provide a further understanding of the embodiments described hereinbelow, and are incorporated in and constitute a part of this specification. The drawings illustrate various embodiments and, together with the description, serve to explain principles of the disclosure. In the drawings, the sizes, thicknesses, ratios, and dimensions of the elements may be exaggerated for ease of description and for clarity. Like reference numbers and/or like reference characters refer to like elements throughout. In the drawings:

FIG. 1 is a perspective view of a display device according to an embodiment that is constructed according to principles of the invention;

FIG. 2 is a cross-sectional view of a display device according to an embodiment;

FIG. 3 is an enlarged plan view partially illustrating a display device according to an embodiment;

FIG. 4 is a cross-sectional view of a display device according to an embodiment; and

FIGS. 5A to 5D are cross-sectional views of display devices according to another embodiment, respectively.

### DETAILED DESCRIPTION OF THE EMBODIMENTS

Hereinafter, embodiments will be described with reference to the drawings.

In this specification, when a component (or region, layer, portion, etc.) is referred to as “on”, “connected”, or “coupled” to another component, it signifies that it is placed/connected/coupled directly on the other component or a third component can be disposed between them.

The same reference numerals or symbols refer to the same elements. In addition, in the drawings, thicknesses, ratios, and dimensions of components are exaggerated for effective description of technical content. “And/or” includes all combinations of one or more that the associated elements may define.

Terms such as first and second may be used to describe various components, but the components should not be limited by the terms. These terms are only used for the purpose of distinguishing one component from other components. For example, without departing from the scope of the present invention, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

Terms such as “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

In the present application, “directly disposed” may signify that there is no layer, film, region, plate, etc. added between a portion such as a layer, film, region, or plate and another portion. For example, “direct disposed” may signify placing two layers or two members without using an additional member such as an adhesive member therebetween.

Unless otherwise defined, all terms (including technical and scientific terms) used in this specification have the same connotation as commonly understood by one of ordinary skill in the art to which this invention belongs. In addition, terms such as terms defined in commonly used dictionaries should be interpreted as having a meaning consistent with the connotation having in the context of the related technology, and should not be interpreted as too ideal or too formal unless explicitly defined here.

In the specification, the term “substituted or unsubstituted” may describe a group that is substituted or unsubstituted with one or more substituents selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, a heterocyclic group, and a combination thereof. Each of the substituents listed above may itself be substituted or unsubstituted. For example, a biphenyl group may be interpreted as an aryl group, or it may be interpreted as a phenyl group substituted with a phenyl group.

In the specification, the term “combined with an adjacent group to form a ring” may be interpreted as a group that is combined with (or bonded to) an adjacent group to form a substituted or unsubstituted hydrocarbon ring or a substituted or unsubstituted heterocycle. The hydrocarbon ring may be aliphatic or aromatic. The heterocycle may be aliphatic or aromatic. The hydrocarbon ring and the heterocycle may each independently be monocyclic or polycyclic. A ring that is formed by adjacent groups being combined with each other may itself be connected to another ring to form a spiro structure.

In the specification, the term “adjacent group” may be interpreted as a substituent that is substituted on an atom directly connected to an atom on which the substituent is substituted, as another substituent that is substituted on an atom on which the substituent is substituted, or as a substituent that is closest, in a three-dimensional perspective, to another substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be straight or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, a 3-methylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond at the middle or at a terminus of an alkyl group having two or more carbon atoms. An alkenyl group may be straight or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond at the middle or at a terminus of an alkyl group having two or more carbon atoms. An alkynyl group may be straight or branched. The number of carbon atoms in an alkynyl group is particularly not limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quarterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, or two substituents thereof may be combined with each other to form a spiro structure. Examples of a substituted fluorenyl may include the groups shown below, but embodiments are not limited thereto.

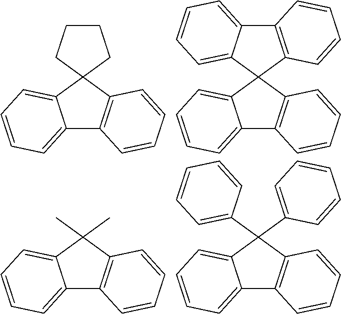

In the specification, a heterocyclic group may be any functional group or substituent derived from a cyclic group that includes, as a heteroatom, at least one of B, O, N, P, Si, and S. A heterocyclic group may be aliphatic or aromatic. An aromatic heterocyclic group may be a heteroaryl group. An aliphatic heterocycle and an aromatic heterocycle may each independently be monocyclic or polycyclic.

In the specification, in a case that a heterocyclic group includes two or more heteroatoms, the two or more heteroatoms may be the same as or different from each other. The number of ring-forming carbon atoms in a heterocyclic group may be 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyridopyrimidine group, a pyridopyrazine group, a pyrazinopyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

A heteroaryl group that includes sulfur(S) as a heteroatom may be a benzothiophene group, but embodiments are not limited thereto. A heteroaryl group that includes sulfur(S) as a heteroatom may also be a thienopyridine group, a thienopyrimidine group, a thienopyridazine group, a thienopyrazine group, a thienotriazine group, a thienotetrazine group, a thiazolopyridine group, a thiazolopyrimidine group, a thiazolopyridazine group, a thiazolopyrazine group, a thiazolotriazine group, a thiazolotetrazine group, a benzothiadiazole group, a thiadiazolepyridine group, a thiadiazolepyrimidine group, a thiadiazolepyridazine group, a thiadiazolepyrazine group, a thiadiazoletriazine group, a thiadiazoletetrazine group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

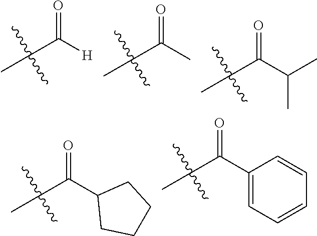

In the specification, the number of carbon atoms in sulfinyl group or in a sulfonyl group is not particularly limited, and may be 1 to 30. A sulfinyl group may be an alkylsulfinyl group or an arylsulfinyl group. A sulfonyl group may be an alkylsulfonyl group or an arylsulfonyl group.

In the specification, a thio group may be an alkylthio group or an arylthiol group. A thio group may be a sulfur atom that is combined with an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments are not limited thereto.

In the specification, an oxy group may be an oxygen atom that is combined with an alkyl group or an aryl group as defined above. An oxy group may be an alkoxy group or an aryloxy group. An alkoxy group may be straight, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is combined with an alkyl group or an aryl group as defined above. A boron group may be an alkylboron group or an arylboron group. Examples of a boron group may include a dimethylboron group, a dichtlyboron group, a t-butylmethylboron group, a diphenylboron group, a phenylboron group, etc., but embodiments are not limited thereto.

In the specification, the number of carbon atoms in an amine group is not particularly limited, and may be 1 to 30. An amine group may be an alkylamine group or an arylamine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylboron group, an alkylsilyl group, or an alkylamine group may be the same as an example of an alkyl group as described above.

In the specification, an aryl group within an aryloxy group, an arylthio group, an arylsulfoxy group, an arylboron group, an arylsilyl group, or an arylamine group may be the same as an example of an aryl group as described above.

In the specification, a direct bond may be a single bond.

In the specification, the symbols

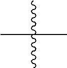

and —* each represent a bond to a neighboring atom in a corresponding formula or moiety.

Hereinafter, a display device according to an embodiment of will be described with reference to the drawings.

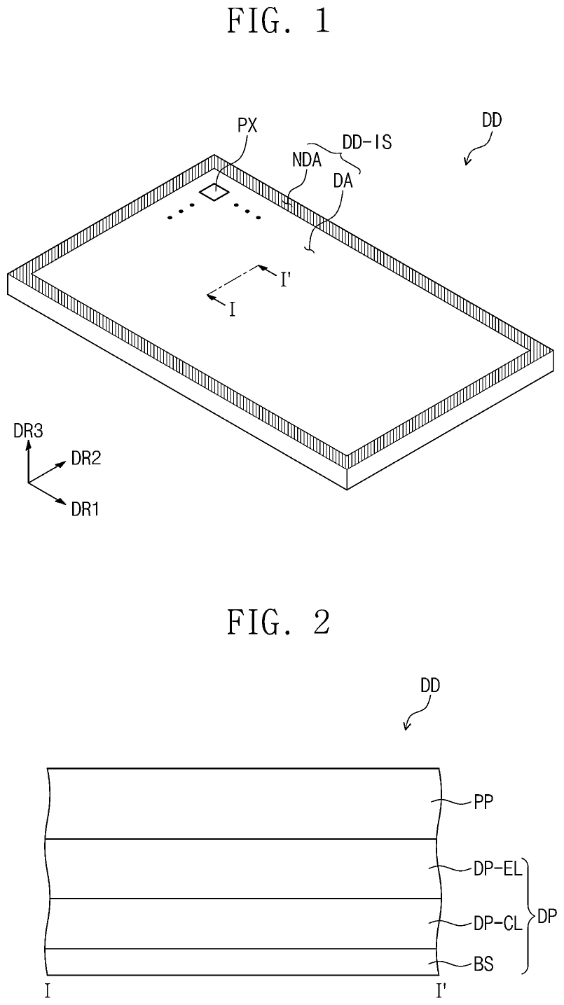

FIG. 1 is a perspective view illustrating a display device DD according to an embodiment. The display device DD provided with a plane-type display surface DD-IS is illustrated in FIG. 1, but an embodiment is not limited thereto. The display device DD may include a curved display surface or a cubic display surface. The cubic display surface may include a plurality of display regions respectively indicating directions different from each other.

The display surface DD-IS may include a display region DA and a non-display region NDA. A pixel PX is disposed in the display region DA, and is not disposed in the non-display region NDA. The non-display region NDA is defined along a boundary of the display surface DD-IS. The non-display region NDA may surround the display region DA, but an embodiment is not limited thereto. In an embodiment, the non-display region NDA may be omitted, or may be disposed only in a side of the display region DA.

A thickness direction of the display device DD may be parallel to a third direction DR3 which is the normal direction of a plane defined by a first direction DR1 and a second direction DR2. Directions indicated by the first to third directions DR1, DR2, and DR3 described in the present specification are relative concepts, and may be changed to other directions.

In the present specification, the upper surface (or front surface) and the lower surface (rear surface) of members constituting the display device DD may be defined with respect to the third direction DR3. More specifically, of two surfaces facing each other with respect to the third direction DR3 in one member, a surface relatively adjacent to the display surface DD-IS may be defined as the front surface (or upper surface), and the other surface relatively spaced apart from the display surface DD-IS may be defined as the rear surface (or lower surface). In addition, in the present specification, the upper portion and the lower portion may be defined with respect to the third direction DR3. The upper portion may be defined as a portion getting closer to the display surface DD-IS, and the lower portion may be defined as a portion getting farther from the display surface DD-IS.

FIG. 2 is a cross-sectional view of the display device DD taken along line I-I′ of FIG. 1 according to an embodiment.

Referring to FIG. 2, the display device DD may include a display panel DP and an optical layer PP disposed on the display panel DP.

In the display device DD according to an embodiment, the display panel DP may be a light-emitting display panel. For example, the display panel DP may be a quantum dot light-emitting display panel including a quantum dot light-emitting element, but an embodiment is not limited thereto.

The display panel DP may include a display element layer DP-EL. The display element layer DP-EL includes a light-emitting element. The display panel DP may include a base substrate BS, a circuit layer DP-CL disposed on the base substrate BS, and the display element layer DP-EL disposed on the circuit layer DP-CL.

The base substrate BS may be a member that supplies a base plane on which the display element layer DP-EL is disposed. The base substrate BS may be a glass substrate, a metal substrate, a plastic substrate, or the like. However, an embodiment is not limited thereto, and the base substrate BS may be an inorganic layer, an organic layer, or a composite material layer. The base substrate BS may be a flexible substrate easily bendable or foldable.

In an embodiment, the circuit layer DP-CL may be disposed on the base substrate BS, and may include a plurality of transistors. The transistors may respectively include a control electrode, an input electrode, and an output electrode. For example, the circuit layer DP-CL may include a switching transistor and a driving transistor for driving the light-emitting element of the display element layer DP-EL.

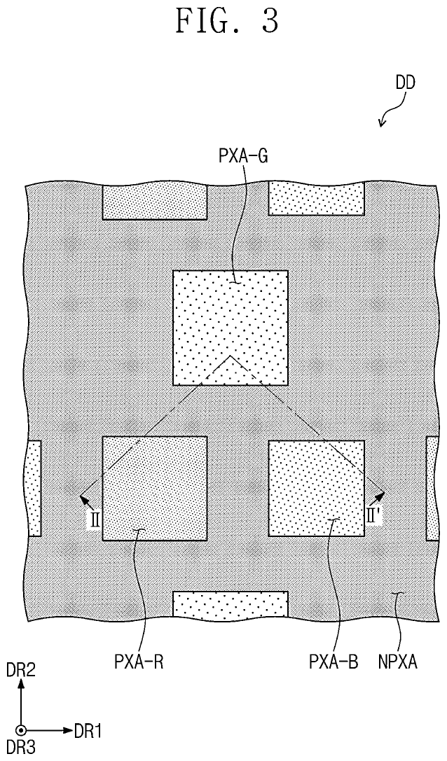

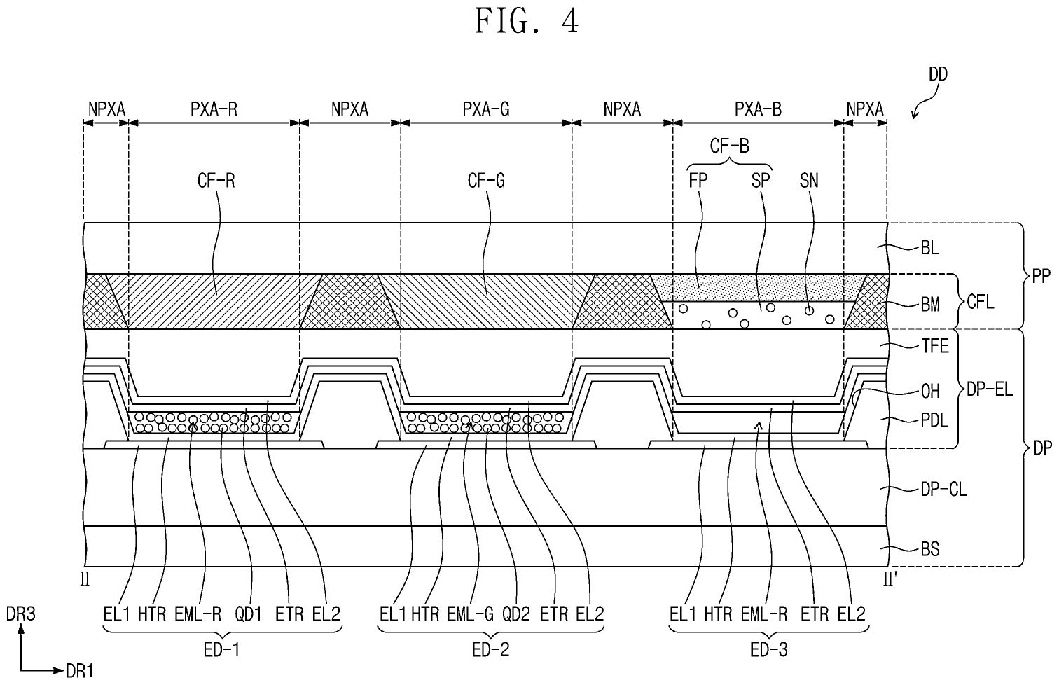

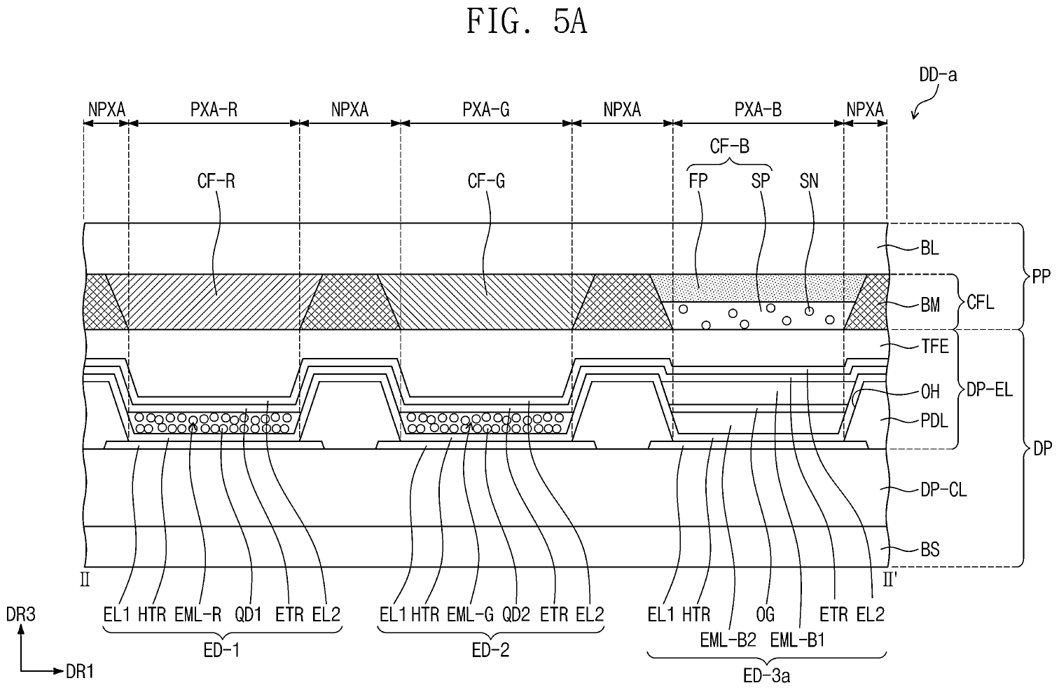

FIG. 3 is an enlarged plan view partially illustrating a display device DD according to an embodiment. FIG. 4 is a cross-sectional view of the display device DD according to an embodiment. FIG. 4 illustrates a portion corresponding to line II-II′ in FIG. 3.

Referring to FIG. 3, the display device DD according to an embodiment may include a plane including three light-emitting regions PXA-R, PXA-G, and PXA-B, and a non-light-emitting region NPXA adjacent thereto. In an embodiment, three kinds of the light-emitting regions PXA-R, PXA-G, and PXA-B illustrated in FIG. 3 may be repeatedly disposed in the entire display region DA (see FIG. 1).

The non-light-emitting region NPXA is disposed around the first to third light-emitting regions PXA-R, PXA-G, and PXA-B. The non-light-emitting region NPXA sets boundaries of the first to third light-emitting regions PXA-R, PXA-G, and PXA-B. The non-light-emitting region NPXA may surround the first to third light-emitting regions PXA-R, PXA-G, and PXA-B. A structure that prevents color mixing between the first to third light-emitting regions PXA-R, PXA-G, and PXA-B, for example, a pixel-defining film PDL (see FIG. 4A), or the like may be disposed in the non-light-emitting region NPXA.

FIG. 3 exemplarily illustrates the first to third light-emitting regions PXA-R, PXA-G, and PXA-B having the same planar shape as each other, and planar areas different from each other, but an embodiment is not limited thereto. At least two of the first to third light-emitting regions PXA-R, PXA-G, and PXA-B may have the same area. Areas of the first to third light-emitting regions PXA-R, PXA-G, and PXA-B may be set depending on colors of light emitted thereby.

FIG. 3 illustrates the first to third light-emitting regions PXA-R, PXA-G, and PXA-B having a rectangular shape, but an embodiment is not limited thereto. On a plane, the first to third light-emitting regions PXA-R, PXA-G, and PXA-B may have a polygonal shape (including a substantial polygonal shape), such as a rhombus or a pentagon, different from the rectangular shape. In an embodiment, the first to third light-emitting regions PXA-R, PXA-G, and PXA-B may have a rectangular shape (a substantial rectangular shape) having a round corner region on a plane.

FIG. 3 exemplarily illustrates that a second light-emitting region PXA-G is disposed on a first row, and a third light-emitting region PXA-B and a first light-emitting region PXA-R are disposed on a second row, but an embodiment is not limited thereto, and a disposition of the first to third light-emitting regions PXA-R, PXA-G, and PXA-B may be variously changed. For example, the first to third light-emitting regions PXA-R, PXA-G, and PXA-B may be disposed on the same row.

Three light-emitting regions PXA-R, PXA-G, and PXA-B emitting blue color light, green color light, and red color light are exemplarily illustrated in the display device DD according to an embodiment illustrated in FIG. 3. For example, the display device DD according to an embodiment may include a red light-emitting region PXA-R, a green light-emitting region PXA-G, and a blue light-emitting region PXA-B distinguished from each other. In the present specification, the red light-emitting region PXA-R, the green light-emitting region PXA-G, the blue light-emitting region PXA-B may be referred to as a first light-emitting region PXA-R, a second light-emitting region PXA-G, and a third light-emitting region PXA-B.

Referring to FIGS. 3 and 4, the first light-emitting region PXA-R, the second light-emitting region PXA-G, and the third light-emitting region PXA-B of the display device DD may respectively correspond to a first light-emitting element ED-1, a second light-emitting element ED-2, and a third light-emitting element ED-3. A plurality of light-emitting elements ED-1, ED-2, and ED-3 may emit light having wavelength regions different from each other. In an embodiment, the display device DD may include the first light-emitting element ED-1 that generates first light, the second light-emitting element ED-2 that generates second light, and the third light-emitting element ED-3 that generates third light. For example, the display device DD may include the first light-emitting element ED-1 that generates red color light, the second light-emitting element ED-2 that generates green color light, and the third light-emitting element ED-3 that generates blue color light. However, an embodiment is not limited thereto, and the first to third light-emitting elements ED-1, ED-2, and ED-3 may emit light having the same wavelength region, or at least one thereof may emit light having a different wavelength region.

In the display device DD according to an embodiment, the light-emitting regions PXA-R, PXA-G, and PXA-B may have areas different from each other. That is, the light-emitting regions PXA-R, PXA-G, and PXA-B may have areas different from each other depending on colors of light emitted by light-emitting layers EML-R, EML-G, and EML-B of the light-emitting elements ED-1, ED-2, and ED-3. In this case, the area may connote an area seen on a plane defined by the first direction DR1 and the second direction DR2. For example, in the display device DD according to an embodiment, the second light-emitting region PXA-G corresponding to the second light-emitting element ED-2 that generates the green color light may have the largest area, and the third light-emitting region PXA-B corresponding to the third light-emitting element ED-3 that generates the blue color light may have the smallest area, but an embodiment is not limited thereto. The light-emitting regions PXA-R, PXA-G, and PXA-B may emit other color light except for the red color light, the green color light, and the blue color, may have the same area, or may be provided with area ratios different from what is illustrated in FIG. 3.

Referring to FIG. 4, the display device DD according to an embodiment may include a display panel DP including a plurality of light-emitting elements ED-1, ED-2, and ED-3, and an optical layer PP disposed on the display panel DP.

The display panel DP may include a base substrate BS, a circuit layer DP-CL and a display element layer DP-EL provided on the base substrate BS. The display element layer DP-EL may include a pixel-defining film PDL, light-emitting elements ED-1, ED-2, and ED-3 disposed between the pixel-defining films PDL or on the pixel-defining film PDL, and an encapsulation layer TFE disposed on the light-emitting elements ED-1, ED-2, and ED-3.

The display element layer DP-EL may include the pixel-defining film PDL. Each of the light-emitting regions PXA-R, PXA-G, and PXA-B may be a region distinguished by the pixel-defining film PDL. The non-light-emitting regions NPXA may be regions between adjacent light-emitting regions PXA-R, PXA-G, and PXA-B, and may be regions corresponding the pixel-defining films PDL. In the present specification, each of the light-emitting regions PXA-R, PXA-G, and PXA-B may correspond to the pixel. Referring to FIG. 4, the pixel-defining film PDL may separate the light-emitting elements ED-1, ED-2, and ED-3. In addition, the light-emitting layers EML-R, EML-G, and EML-B of the light-emitting elements ED-1, ED-2, and ED-3 may be disposed in an opening OH defined by the pixel-defining film PDL to separate the light-emitting elements ED-1, ED-2, and ED-3.

The pixel-defining film PDL may be formed of a polymer resin. For example, the pixel-defining film PDL may be formed including a polyacrylate-based resin, or a polyimide-based resin. In addition, the pixel-defining film PDL may be formed further including an inorganic material as well as the polymer resin. The pixel-defining film PDL may be formed including a light-absorbing material, or a black pigment or dye. The pixel-defining film PDL formed including the black pigment or dye may perform a black pixel-defining film. In a case that the pixel-defining film PDL is formed, carbon black, or the like may be used as the black pigment or dye, but an embodiment is not limited thereto.

The pixel-defining film PDL may be formed of an inorganic material. For example, the pixel-defining film PDL may be formed including silicon nitride (SiNₓ), silicon oxide (SiOₓ), silicon oxynitride (SiOₓN_{y}). The pixel-defining film PDL may define the light-emitting regions PXA-R, PXA-G, and PXA-B. The light-emitting regions PXA-R, PXA-G, and PXA-B and the non-light-emitting region NPXA may be distinguished by the pixel-defining film PDL.

Referring to FIG. 4, the display element layer DP-EL may include the light-emitting elements ED-1, ED-2, and ED-3 disposed between the pixel-defining films PDL. The display device DD according to an embodiment may include the first to third light-emitting elements ED-1, ED-2, and ED-3, and the light-emitting elements ED-1, ED-2, and ED-3 may respectively include the light-emitting layers EML-R, EML-G, and EML-B. The first to third light-emitting elements ED-1, ED-2, and ED-3 according to an embodiment may include a first electrode EL1, a second electrode EL2 facing the first electrode EL1, and a plurality of functional layers disposed between the first electrode EL1 and the second electrode EL2, and including the light-emitting layers EML-R, EML-G, and EML-B.

The plurality of functional layers may include a hole transport region HTR disposed between the first electrode EL1 and the light-emitting layers EML-R, EML-G, and EML-B, and an electron transport region ETR disposed between the light-emitting layers EML-R, EML-G, and EML-B and the second electrode EL2.

The hole transport region HTR and the electron transport region ETR may each include a plurality of sub-functional layers. For example, the hole transport region HTR may include, as the sub-functional layer, a hole injection layer and a hole transport layer, and the electron transport region ETR may include, as the sub-functional layer, an electron injection layer, and an electron transport layer An embodiment is not limited thereto, the hole transport region HTR may further include an electron-blocking layer, or the like as the sub-functional layer, and the electron transport region ETR may further include a hole-blocking layer, or the like as the sub-functional layer.

The first electrode EL1 has a conductive property. The first electrode EL1 may be formed of a metal material, a metal alloy, or a conductive compound. The first electrode EL1 may be an anode or a cathode, but an embodiment is not limited thereto. In addition, the first electrode EL1 may be a pixel electrode. The first electrode EL1 may be a transmissive electrode, a semi-transmissive electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

In a case that the first electrode EL1 is a transmissive electrode, the first electrode EL1 may include transparent conductive oxide, for example, indium-tin oxide (ITO), indium-zinc oxide (IZO), zinc oxide (ZnO), indium-tin-zinc oxide (ITZO), or the like. In a case that the first electrode EL1 is a semi-transmissive electrode or a reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (for example, a mixture of Ag and Mg). In another embodiment, the first electrode EL1 may have a structure composed of a plurality of layers including a reflective film or a semi-transmissive film formed of the materials described above, and a transparent conductive film formed of indium-tin oxide (ITO), indium-zinc oxide (IZO), zinc oxide (ZnO), indium-tin-zinc oxide (ITZO), or the like. For example, the first electrode EL1 may have a three-layered structure of ITO/Ag/ITO, but embodiments are not limited thereto.

The hole transport region HTR is provided on the first electrode EL1. The hole transport region HTR may include a hole injection layer, a hole transport layer, etc. The hole transport region HTR may have a structure having a single layer composed of a single material, a single layer composed of a plurality of different materials, or a plurality of layers composed of a plurality of different materials.

The hole transport region HTR may be formed using various methods such as a vacuum deposition method, a spin coating method, a casting method, an LB (Langmuir-Blodgett) method, an inkjet printing method, a laser printing method, a laser induced thermal imaging (LITI) method, or the like.

For example, the hole transport region HTR may include a carbazole-based derivative such as N-phenylcarbazole or polyvinylcarbazole, a fluorene-based derivative, a triphenylamine derivative such as TPD (N,N′-bis(3-methylphenyl)-N,N′-diphenyl-[1,1-biphenyl]-4,4′-diamine), TCTA (4,4′,4″-tris(N-carbazolyl)triphenylamine), NPD (N,N′-di(naphthalene-1-yl)-N,N′-diphenyl-benzidine), TAPC (4,4′-cyclohexylidenebis[N,N-bis(4-methylphenyl)benzenamine]), HMTPD (4,4′-bis[N,N′-(3-tolyl)amino]-3,3′-dimethylbiphenyl), mCP (1,3-bis(N-carbazolyl)benzene), or the like.

The hole transport region HTR may have a thickness of about 5 nm to about 1500 nm, for example, about 10 nm to about 500 nm. In a case that the thickness of the hole transport region HTR satisfies the above range, satisfactory hole transport characteristics may be obtained without a substantial increase in a driving voltage.

The light-emitting layers EML-R, EML-G, and EML-B are provided on the hole transport region HTR. The light-emitting elements ED-1, ED-2, and ED-3 may respectively include the light-emitting layers EML-R, EML-G, and EML-B. The first light-emitting element ED-1 may include a first light-emitting layer EML-R, the second light-emitting element ED-2 may include a second light-emitting layer EML-G, and the third light-emitting element ED-3 may include a third light-emitting layer EML-B.

The light-emitting layers EML-R, EML-G, and EML-B may include a host and a dopant. In an embodiment, the first light-emitting layer EML-R may include a first host and a first dopant, the second light-emitting layer EML-G may include a second host and a second dopant, and the third light-emitting layer EML-B may include a third host and a third dopant.

In an embodiment, the first and second light-emitting layers EML-R and EML-G may respectively include first and second quantum dots QD1 and QD2 as the first and second dopants. In an embodiment, the first and second light-emitting layers EML-R and EML-G may include the first and second quantum dots QD1 and QD2 as the first and second dopants, and may further include the first and second hosts. In an embodiment, the third light-emitting layer EML-B may include an organic material as the third dopant. In an embodiment, the third light-emitting layer EML-B may include the organic material as the third dopant, and may further include the third host of the organic material. For example, the third dopant may be a thermally activated delayed fluorescence (TADF) dopant.

The first light-emitting layer EML-R may include a first quantum dot QD1, and the second light-emitting layer EML-G may include a second quantum dot QD2. The first light-emitting layer EML-R may include a plurality of first quantum dots QD1, and the second light-emitting layer EML-G may include a plurality of second quantum dots QD2. The first and second quantum dots QD1 and QD2 respectively included in the first and second light-emitting layers EML-R and EML-G may be stacked to constitute a layer. FIG. 4 illustrates as an example that the first and second quantum dots QD1 and QD2 having a round cross-sectional shape are arranged to constitute approximately two layers, but embodiments are not limited thereto. For example, an arrangement of the first and second quantum dots QD1 and QD2 may differ depending on thicknesses of the first and second light-emitting layers EML-R and EML-G, shapes of the first and second quantum dots QD1 and QD2 included in the first and second light-emitting layers EML-R and EML-G, average diameters of the first and second quantum dots QD1 and QD2, etc. For example, in the first and second light-emitting layers EML-R and EML-G, the first and second quantum dots QD1 and QD2 may be aligned adjacent to each other so as to constitute a single layer, or may be aligned so as to constitute a plurality of layers such as two layers or three layers.

The first and second quantum dots QD1 and QD2 may each include a core and a shell surrounding the core. Accordingly, the first and second quantum dots QD1 and QD2 may each have a core-shell structure. In an embodiment, the first and second quantum dots QD1 and QD2 respectively included in the first and second light-emitting elements ED-1 and ED-2 nay be formed of different core materials. In another embodiment, the first and second quantum dots QD1 and QD2 may each be formed of a same core material, or a quantum dot selected from each of the first and second quantum dots QD1 and QD2 may each be formed of a same core material, and the remainder thereof may be formed of core materials that are different therefrom.

In an embodiment, the first and second quantum dots QD1 and QD2 may have different diameters. For example, the second quantum dot QD2 used in the second light-emitting element ED-2 that emits light having a relatively shorter wavelength region may have a relatively smaller average diameter than the first quantum dot QD1 used in the first light-emitting element ED-1 that emits light having a relatively longer wavelength region. In the present specification, an average diameter may be an arithmetic average value of diameters of the quantum dot particles. The diameter of a quantum dot particle may be an average value of widths of quantum dot particles as measured on cross-sections thereof. However, a relationship of the average diameters of the first and second quantum dots QD1 and QD2 is not limited to what is described above. FIG. 4 illustrates that a size of each of a plurality of first quantum dots QD1 and a size of each of a plurality of second quantum dot QD2 are similar to each other. However, in another embodiment, sizes of the first and second quantum dots QD1 and QD2 respectively included in the first and second light-emitting elements ED-1 and ED-2 may be different from each other.

The quantum dots QD1 and QD2 may be crystals of semiconductor compounds. The quantum dots QD1 and QD2 may emit light having various light-emitting wavelengths depending on sizes thereof. The quantum dots QD1 and QD2 may emit light having various light-emitting wavelengths by controlling the ratios of elements in a quantum compound constituting the quantum dots QD1 and QD2.

For example, the quantum dots QD1 and QD2 may each independently have diameters in a range of about 1 nm to about 10 nm. The quantum dots QD1 and QD2 may be synthesized in a wet chemical process, an organometallic chemical deposition process, a molecular beam epitaxy process, a process similar thereto, or the like.

A wet chemical process of manufacturing the quantum dots QD1 and QD2 is a method of growing a quantum dot particle crystal after mixing an organic solvent and a precursor material. In a case that the quantum dot particle crystal grows, the organic solvent may naturally serve as a dispersant coordinated to a surface of the quantum dot crystal, and may control growth of the particle crystal. Accordingly, the wet chemical process may be more readily performed than a vapor deposition process such as metal organic chemical vapor deposition (MOCVD) or molecular beam epitaxy (MBE), and may control growth of the quantum dot particle through a low-cost process.

The core of the quantum dots QD1 and QD2 may each independently be a Group II-VI compound, a Group III-V compound, a Group III-VI compound, a Group I-III-VI compound, a Group IV-VI compound, a Group IV element, a Group IV compound, or a combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a tertiary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; or a combination thereof. In an embodiment, a Group II-VI semiconductor compound may further include a Group I metal and/or a Group IV element. Examples of a Group I-II-VI compound may include CuSnS and CuZnS, and examples of a Group II-IV-VI compound may include ZnSnS, or the like. Examples of a Group I-II-IV-VI compound may include a quaternary compound selected from the group consisting of CuzZnSnS₂, CuzZnSnS₄, CuzZnSnSe₄, Ag₂ZnSnS₂, and a mixture thereof.

Examples of a Group III-VI compound may include: a binary compound such as In₂S₃, or In₂Se₃; a ternary compound such as InGaS₃, or InGaSe₃; or a combination thereof.

Examples of a Group I-III-VI compound may include: a ternary compound selected from the group consisting of AgInS, AgInS₂, CuInS, CuInS₂, AgGaS₂, CuGaS₂, CuGaO₂, AgGaO₂, AgAlO₂, and a mixture thereof; a quaternary compound such as AgInGaS₂, or CuInGaS₂; or a combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAINP, InAINAs, InAINSb, InAlPAs, InAlPSb, and a mixture thereof; or a combination thereof. In an embodiment, a Group III-V compound may further include a Group II metal. Examples of a Group III-II-V compound may include InZnP and the like.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or a combination thereof.

Examples of a Group II-IV-V semiconductor compound may include a ternary compound selected from the group consisting of ZnSnP, ZnSnP₂, ZnSnAs₂, ZnGeP₂, ZnGeAs₂, CdSnP₂, CdGeP₂, and a mixture thereof.

Examples of a Group IV element may include Si, Ge, and a mixture thereof. Examples of a Group IV compound may include a binary compound selected from the group consisting of SiC, SiGe, and a mixture thereof.

Each element included in a compound, such as a binary compound, a ternary compound, or a quaternary compound, may be present in a particle at a uniform concentration or at a non-uniform concentration. For example, a formula representing a quantum dot may indicate the elements that are included in the quantum dot compound, but an elemental ratio in the compound may vary. For example, AgInGaS₂ may indicate AgInₓGa₁₋ₓS₂ (where x is a real number between 0 to 1).

A binary compound, a ternary compound, or a quaternary compound may be present in a particle at a uniform concentration distribution, or may be present in a particle at a partially different concentration distribution. In embodiments, the quantum dots QD1 and QD2 may each have a core/shell structure in which a quantum dot core is surrounded by a quantum dot shell. A quantum dot having a core/shell structure may have a concentration gradient in which a concentration of an element that is present in the shell decreases toward the core.

In embodiments, the quantum dots QD1 and QD2 may have a core/shell structure including a core and a shell surrounding the core as described above. The shell of the quantum dots QD1 and QD2 may each serve as a protective layer that prevents chemical modification of the core to maintain semiconductor properties and/or may serve as a charging layer that imparts electrophoretic characteristics to the quantum dots QD1 and QD2. The shell may be single-layered or multi-layered. Examples of a shell of the quantum dots QD1 and QD2 may include a metal oxide, a non-metal oxide, a semiconductor compound, a combination thereof, or the like.

Examples of a metal oxide or a non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but embodiments are not limited thereto.

The quantum dot may have a full width at half maximum (FWHM) of an emission spectrum equal to or less than about 45 nm. For example, the quantum dot may have a FWHM of an emission spectrum equal to or less than about 40 nm. For example, the quantum dot may have a FWHM of an emission spectrum equal to or less than about 30 nm. Color purity or color reproducibility may be improved in any of the above ranges. Light emitted from the quantum dots QD1 and QD2 may be emitted in all directions, so that an optical viewing angle may be improved.

The shape of the quantum dots QD1 and QD2 may be any shape that is used in the related art. For example, the quantum dots QD1 and QD2 may each independently have a spherical shape, a pyramid shape, a multi-arm shape, or a cubic shape, a nano-tube shape, a nano-wire shape, a nano fiber shape, a nano-plate shape, or the like.

Since the energy band gaps of the quantum dots QD1 and QD2 may be controlled by controlling the sizes of the quantum dots, or by adjusting the elemental ratios in a quantum dot compound, light of various wavelengths may be obtained from the light-emitting layers EML-R and EML-G including the quantum dots QD1 and QD2. Accordingly, the quantum dots as described above (having different sizes, or having different ratios of the elements in the quantum dot compound) may be implements in a light-emitting element that emits light of various wavelengths. For example, the sizes of the quantum dots, or the elemental ratios of a quantum dot compound may be selectively controlled to emit red color light or green color light. For example, the size of the quantum dot or the elemental ratio of a quantum dot compound may be controlled so that the first quantum dot QD1 may emit the red color light, and the second quantum dot QD2 may emit the green color light.

The third light-emitting layer EML-B may include an organic material as a light-emitting material. The third light-emitting layer EML-B may include a fluorescent or phosphorescent material. For example, the third light-emitting layer EML-B may include an anthracene derivative, a pyrene derivative, a fluoranthene derivative, a chrysene derivative, a dihydrobenzanthracene derivative, or a triphenylene derivative. In an embodiment, the third light-emitting layer EML-B may include an organometallic complex as a light-emitting material. However, a material included in the third light-emitting layer EML-B is not limited to the materials described above, and may include other materials.

The third light-emitting layer EML-B may generate blue color light. The third light-emitting layer EML-B may generate light having a wavelength in a range of about 410 nm to about 480 nm.

The third light-emitting layer EML-B may include a compound represented by Chemical Formula E-1. The third host included in the third light-emitting layer EML-B may include the compound represented by Chemical Formula E-1. The compound represented by Chemical Formula E-1 may be used as a fluorescent host material.

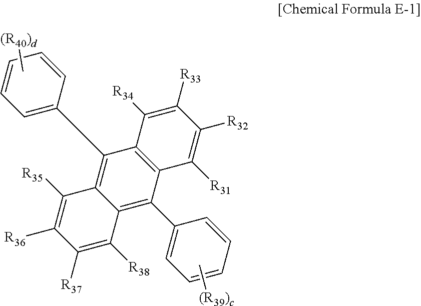

In Chemical Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be combined with an adjacent group to form a ring. For example, R₃₁ to R₄₀ may be combined with an adjacent group to form a saturated hydrocarbon ring, an unsaturated hydrocarbon ring, a saturated heterocycle, or an unsaturated heterocycle.

In Chemical Formula E-1, c and d may each independently be an integer from 0 to 5.

In an embodiment, the compound represented by Chemical Formula E-1 may be any compound selected from Compounds E1 to E19.

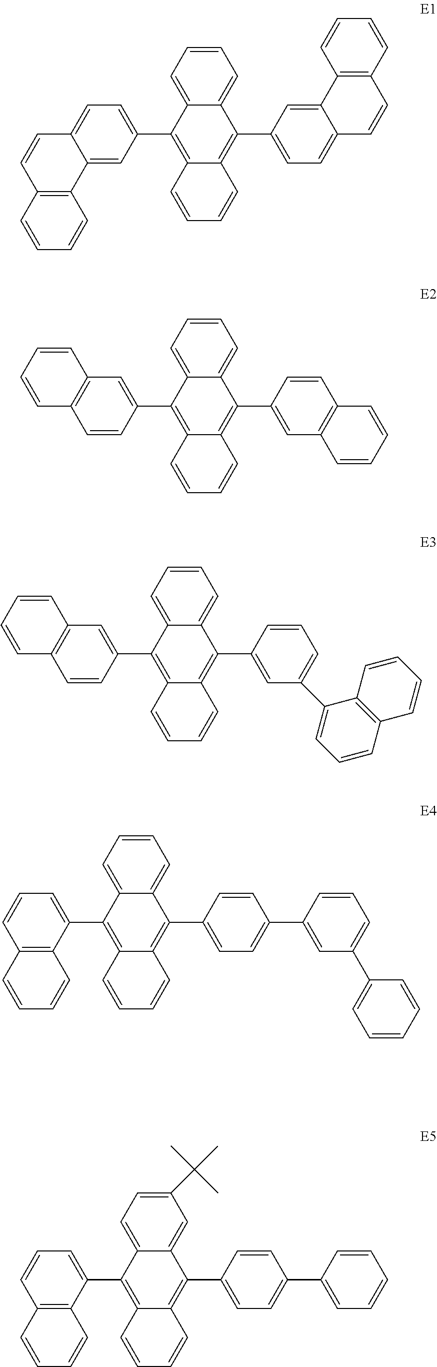

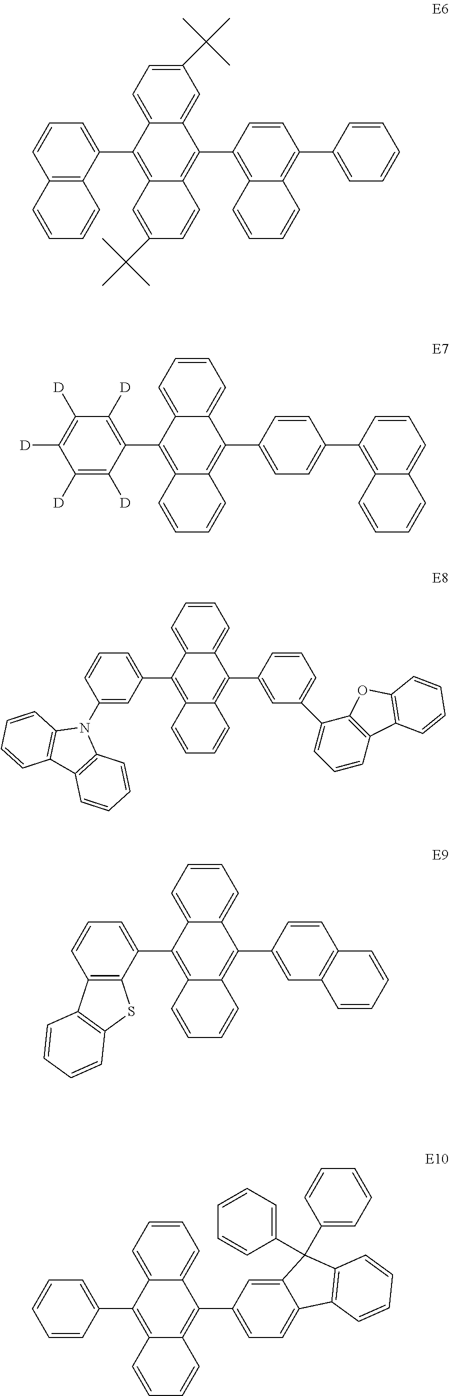

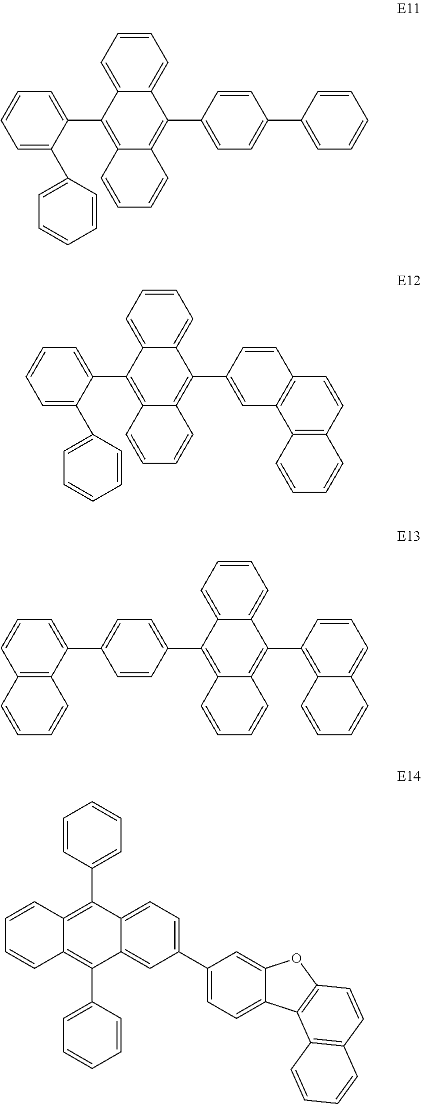

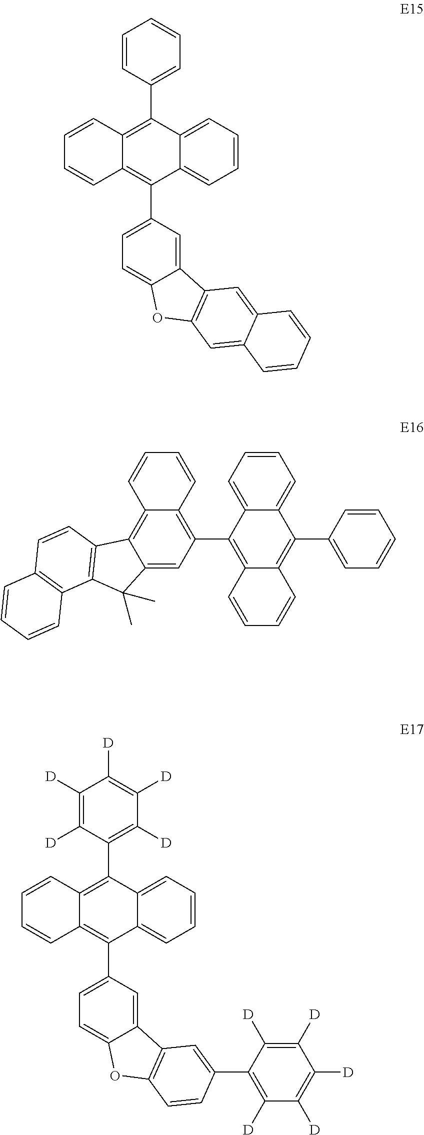

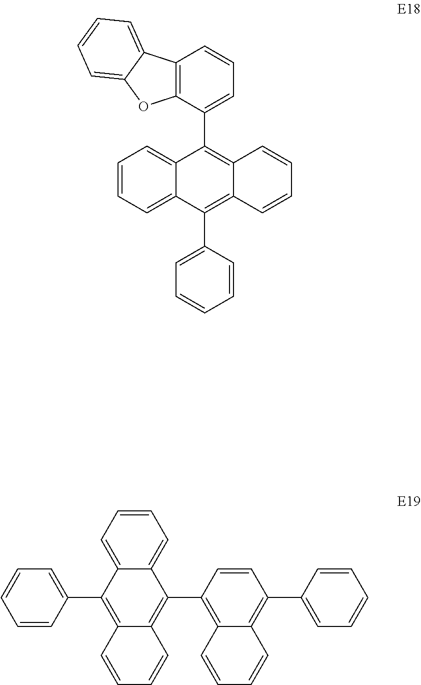

In an embodiment, the third light-emitting layer EML-B may include a compound represented by Chemical Formula E-2a or Chemical Formula E-2b. The third host included in the third light-emitting layer EML-B may include a compound represented by Chemical Formula E-2a or Chemical Formula E-2b. The compound represented by Chemical Formula E-2a or Chemical Formula E-2b may be used as a phosphorescent host material.

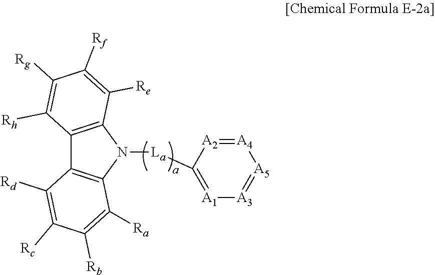

In Chemical Formula E-2a, a may be an integer from 0 to 10; and Lₐ may be a direct bond, a substituted or unsubstituted arylene group having 6 to 30 ring-forming carbon atoms, or a substituted or unsubstituted heteroarylene group having 2 to 30 ring-forming carbon atoms. If a is equal to or greater than 2, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Chemical Formula E-2a, A₁ to A₅ may each independently be N or C(Rᵢ). In Chemical Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 10 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be combined with an adjacent group to form a ring. For example, Rₐ to Rᵢ may be combined with an adjacent group to form a hydrocarbon ring or a heterocycle including N, O, S, or the like as a ring-forming atom.

In Chemical Formula E-2a, two or three of A₁ to A₅ may each be N, and the remainder of A₁ to A₅ may each independently be C(Rᵢ).

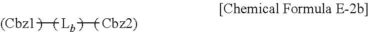

In Chemical Formula E-2b, Cbz1 and Cbz2 may each independently be an unsubstituted carbazole group or a carbazole group substituted with an aryl group having 6 to 30 ring-forming carbon atoms. In Chemical Formula E-2b, L_{b} may be a direct bond, a substituted or unsubstituted arylene group having 6 to 30 ring-forming carbon atoms, or a substituted or unsubstituted heteroarylene group having 2 to 30 ring-forming carbon atoms. In Chemical Formula E-2b, b may be an integer from 0 to 10. In a case that b is equal to or greater than 2, multiple L_{b} groups may each independently be a substituted or unsubstituted arylene group having 6 to 30 ring-forming carbon atoms, or a substituted or unsubstituted heteroarylene group having 2 to 30 ring-forming carbon atoms.

In an embodiment, the compound represented by Chemical Formula E-2a or Chemical Formula E-2b may be any compound selected from Compound Group E-2. However, the compounds listed in Compound Group E-2 are only examples, and the compound represented by Chemical Formula E-2a or Chemical Formula E-2b is not limited to Compound Group E-2.

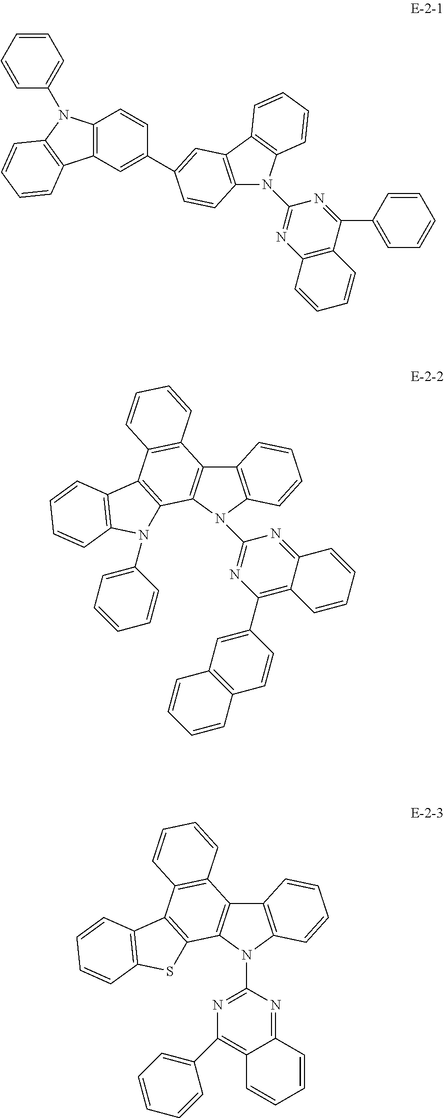 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

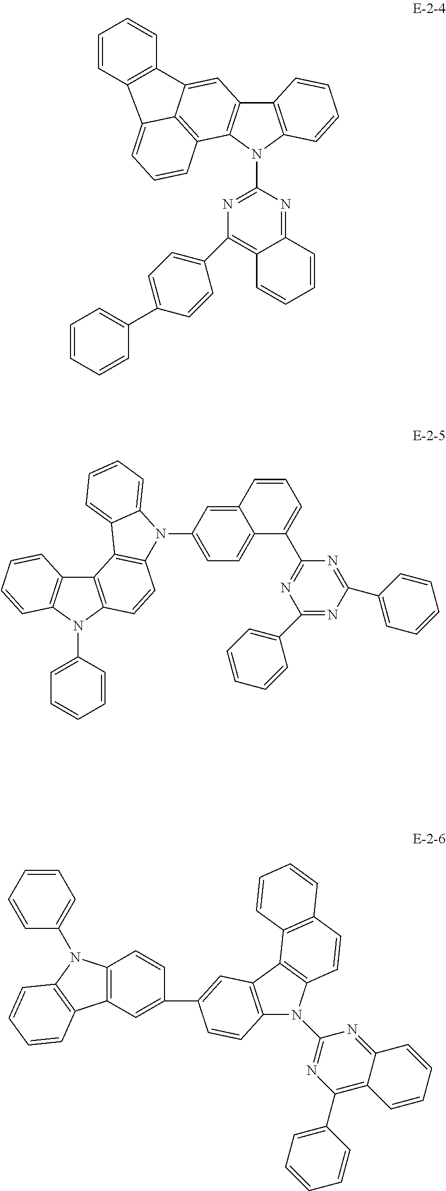 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

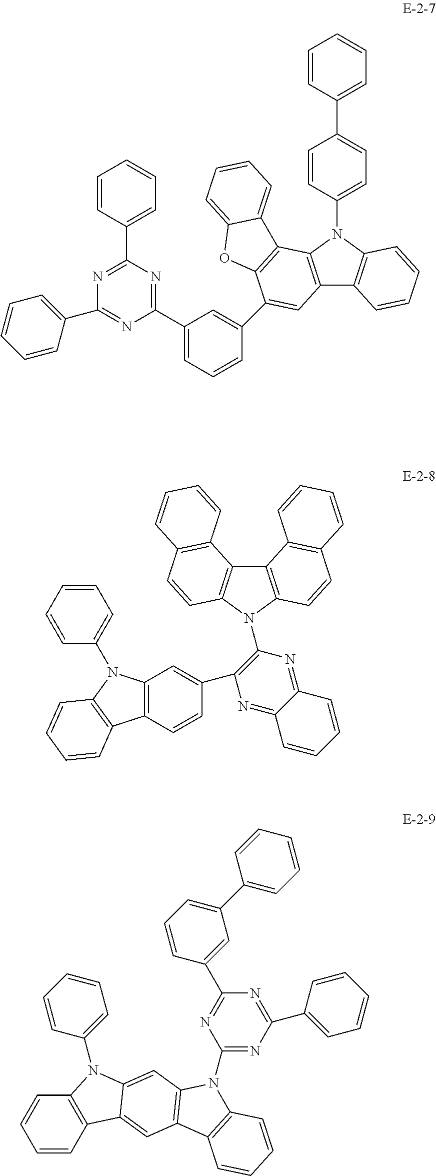 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

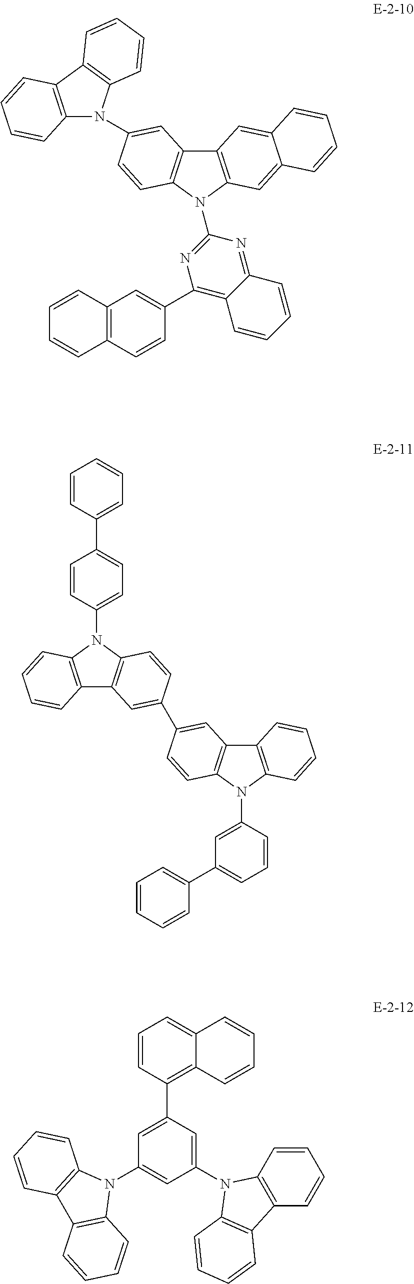 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

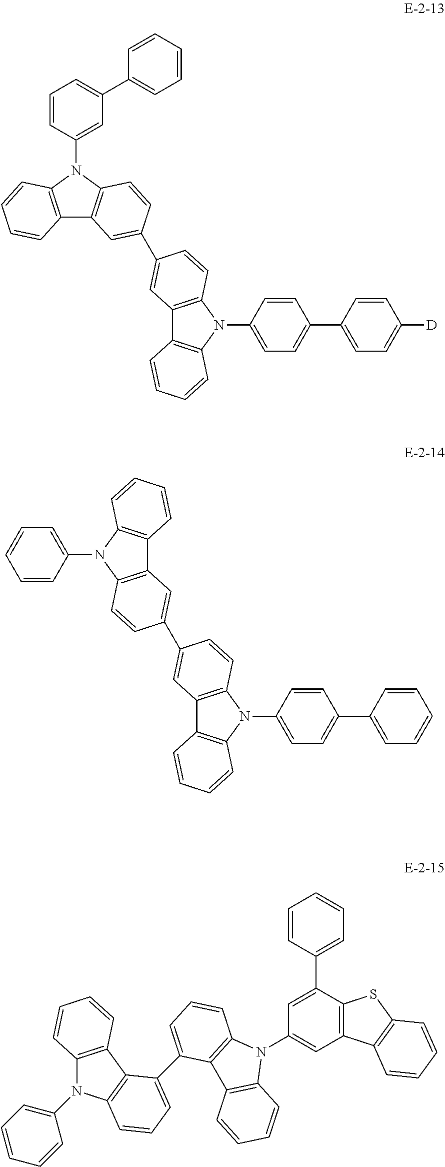 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

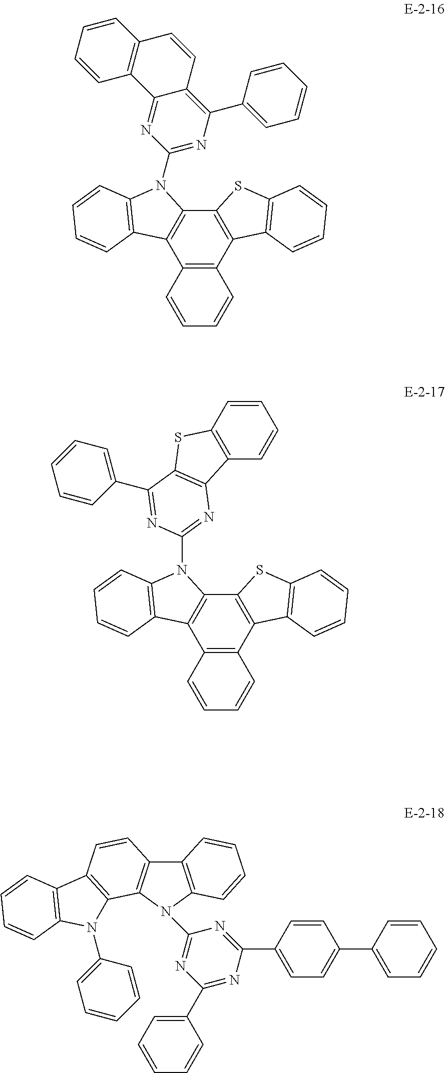 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

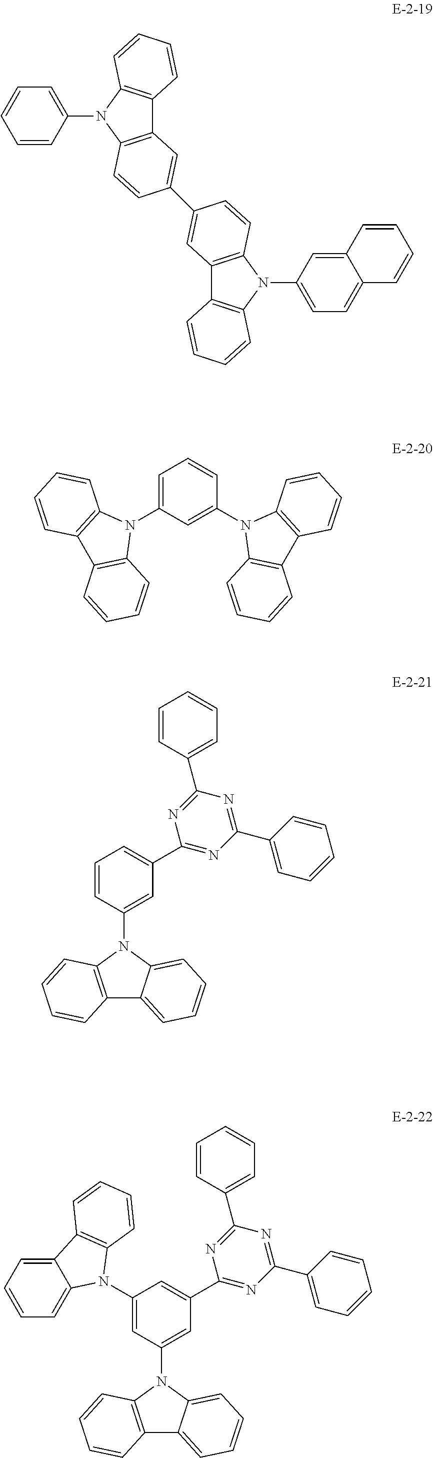 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

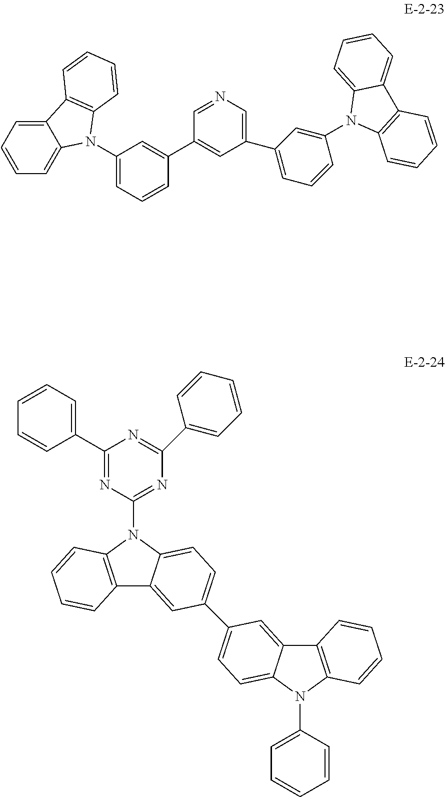 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The third light-emitting layer EML-B may further include a material of the related art as a host material. For example, the third light-emitting layer EML-B may include, as the host material, at least one of BCPDS (bis(4-(9H-carbazol-9-yl)phenyl)diphenylsilane), POPCPA ((4-(1-(4-(diphenylamino)phenyl)cyclohexyl)phenyl)diphenyl-phosphineoxide), DPEPO (bis[2-(diphenylphosphino)phenyl]etheroxide), CBP (4,4′-bis(N-carbazolyl)-1,1′-biphenyl), mCP (1,3-bis(carbazol-9-yl)benzene), PPF (2,8-bis(diphenylphosphoryl)dibenzo[b,d]furan), TCTA (4,4′,4″-tris(carbazol-9-yl)-triphenylamine), or TPBi (1,3,5-tris(1-phenyl-1H-benzo[d]imidazole-2-yl)benzene). However, embodiments are not limited thereto. For example, Alq3 (tris(8-hydroxyquinolino)aluminum), ADN (9,10-di(naphthalene-2-yl)anthracene), TBADN (2-tert-butyl-9,10-di(naphth-2-yl)anthracene), DSA (distyrylarylene), CDBP (4,4′-bis(9-carbazolyl)-2,2′-dimethyl-biphenyl), MADN (2-methyl-9,10-bis(naphthalen-2-yl)anthracene), CP1 (hexaphenylcyclotriphosphazene), UGH2 (1,4-bis(triphenylsilyl)benzene), DPSiO3 (hexaphenylcyclotrisiloxane), DPSiO4 (octaphenylcyclotetrasiloxane), or the like may be used as a host material.

In an embodiment, the third light-emitting layer EML-B may include a compound represented by Chemical Formula M-a. The third dopant included in the third light-emitting layer EML-B may include a compound represented by Chemical Formula M-a. The compound represented by Chemical Formula M-a may be used as a phosphorescent dopant material.

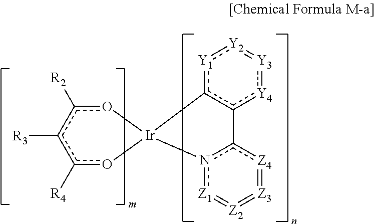

In Chemical Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be combined with an adjacent group to form a ring. In Chemical Formula M-a, m may be 0 or 1, and n may be 2 or 3. In Chemical Formula M-a, in a case that m is 0, n may be 3, and in a case that m is 1, n may be 2.

In an embodiment, the compound represented by Chemical Formula M-a may be any compound selected from Compounds M-a1 to M-a25. However, Compounds M-a1 to M-a25 are only examples, and the compound represented by Chemical Formula M-a is not limited to Compounds M-a1 to M-a25.

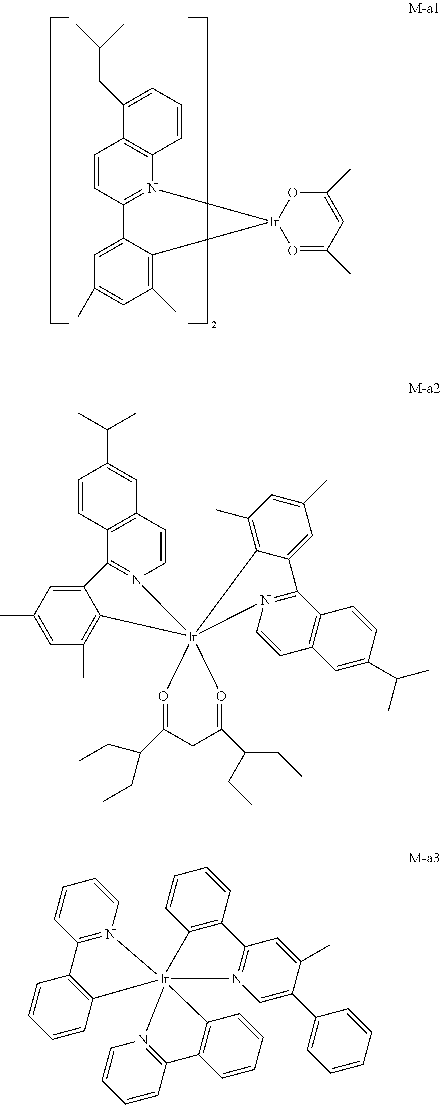

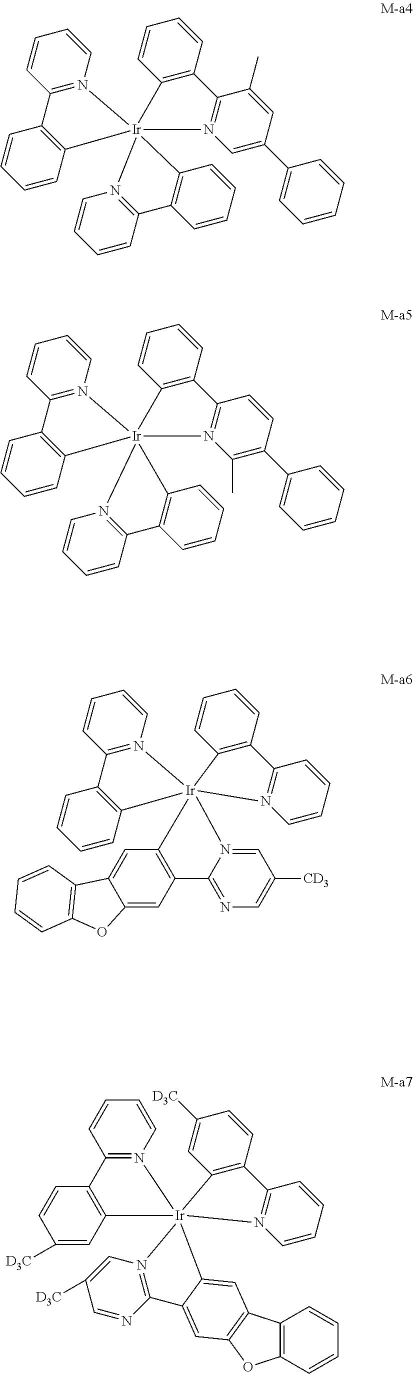

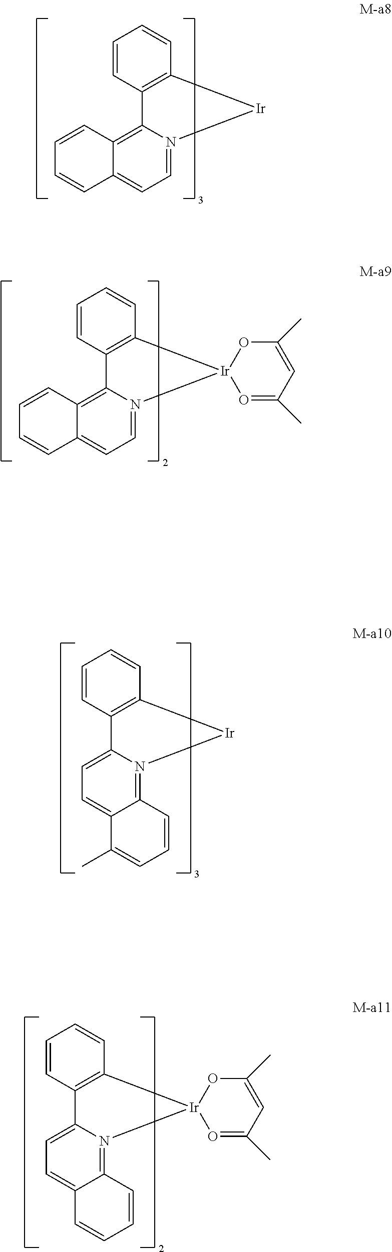

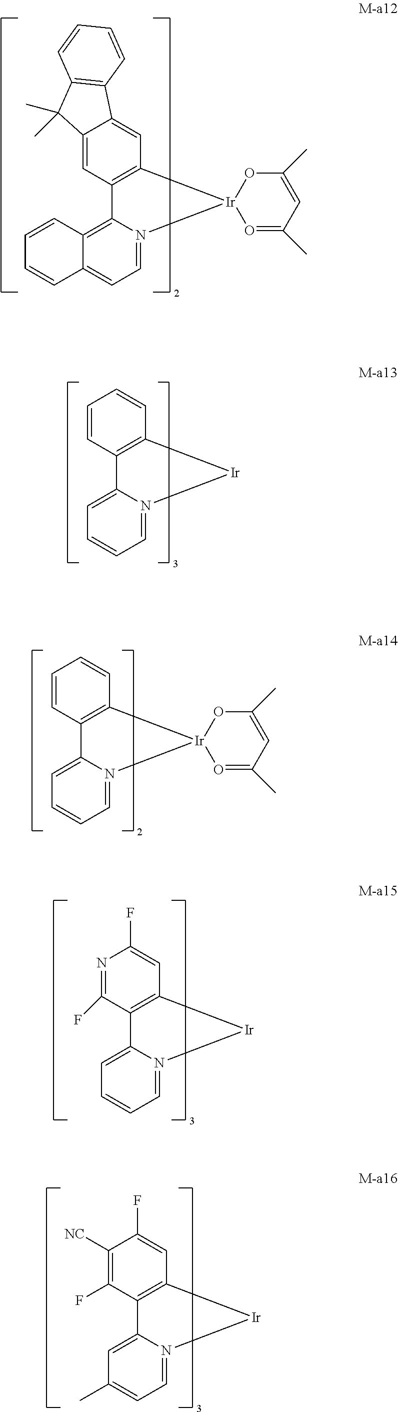

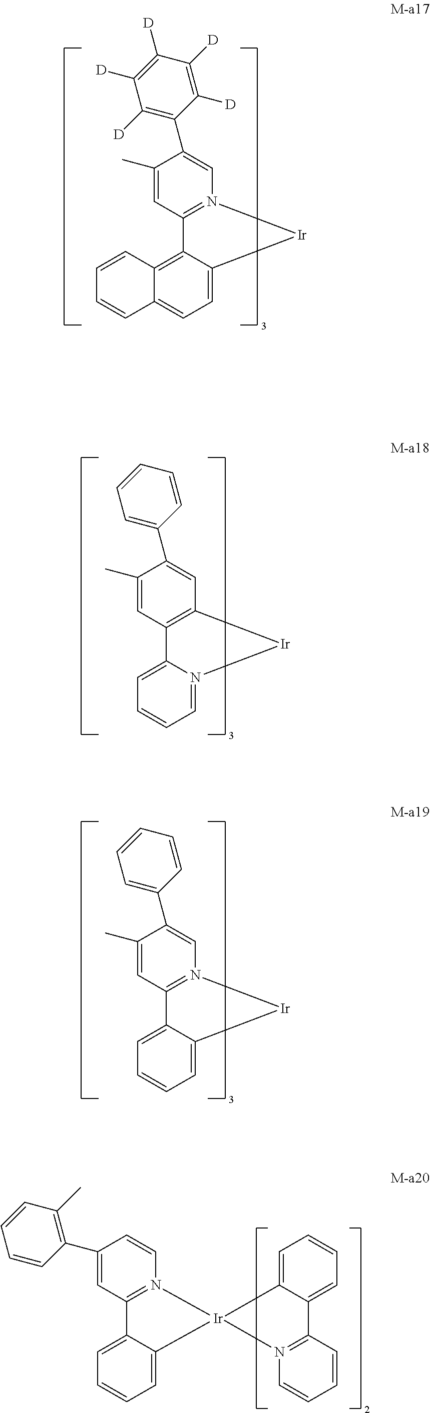

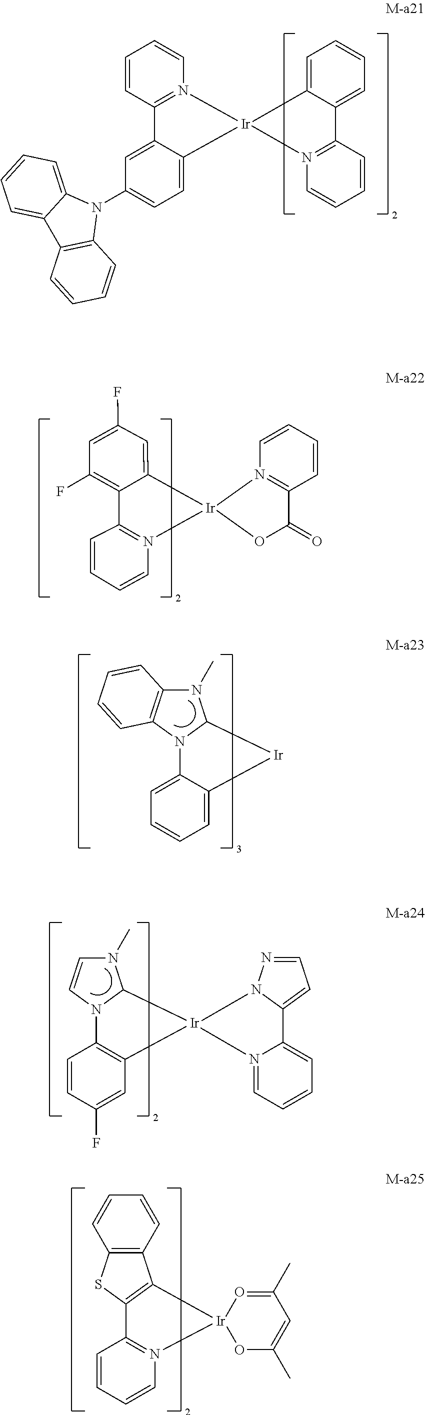

In an embodiment, the third light-emitting layer EML-B may include a compound represented by one of Chemical Formula F-a to Chemical Formula F-c. The third dopant included in the third light-emitting layer EML-B may include a compound represented by one of Chemical Formula F-a to Chemical Formula F-c. The compounds represented by Chemical Formula F-a to Chemical Formula F-c may each be used as a fluorescent dopant material.

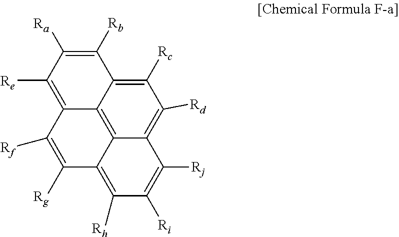

In Chemical Formula F-a, two of Rₐ to Rᵢ may each independently be substituted with a group represented by *—NAr₁Ar₂. The remainder of Rₐ to Rᵢ that are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Chemical Formula F-a, in the group represented by *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group including O or S as a ring-forming atom.

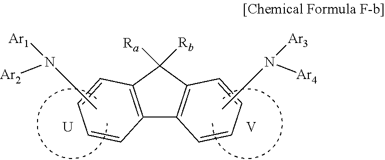

In Chemical Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be combined with an adjacent group to form a ring. In Chemical Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may be a heteroaryl group including O or S as a ring-forming atom.

In Chemical Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Chemical Formula F-b, the number of rings represented by U and V may each independently be 0 or 1. When the number of U or V is 1, a fused ring may be present at a portion indicated by U or V, and in a case that the number of U or V is 0, a fused ring may not be present at the portion indicated by U or V. In a case that the number of U is 0 and the number of V is 1, or in a case that the number of U is 1 and the number of V is 0, a fused ring having the fluorene core of Chemical Formula F-b may be a cyclic compound having four rings. In a case that the number of U and V is each 0, a fused ring having the fluorene core of Chemical Formula F-b may be a cyclic compound having three rings. In a case that the number of U and V is each 1, a fused ring having the fluorene core of Chemical Formula F-b may be a cyclic compound having five rings.

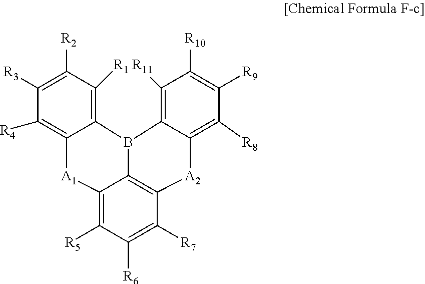

In Chemical formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Chemical Formula F-c, R₁ to R₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be combined with an adjacent group to form a ring.

In Chemical Formula F-c, A₁ and A₂ may each independently be combined with a substituent of an adjacent ring to form a condensed ring. For example, in a case that A₁ and A₂ are each independently N(Rₘ), A₁ may be combined with R₄ or R₅ to form a condensed ring. For example, A₂ may be combined with R₇ and R₈ to form a condensed ring.

In an embodiment, the third light-emitting layer EML-B may include, as a dopant material of the related art, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino) styryl) naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), or the like.

In an embodiment, the third light-emitting layer EML-B may include a phosphorescent dopant material of the related art. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, FIrpic (iridium(III) bis(4,6-difluorophenylpyridinato-N,C2′)picolinate), Fir6 (bis(2,4-difluorophenylpyridinato)-tetrakis(1-pyrazolyl) borate iridium(III)), or PtOEP (platinum octaethyl porphyrin) may be used as a phosphorescent dopant, but embodiments are not limited thereto.

Meanwhile, FIG. 4 illustrates that in the display device DD according to an embodiment, the light-emitting layers EML-R, EML-G, and EML-B of the first to third light-emitting elements ED-1, ED-2, and ED-3 all have similar thicknesses, but an embodiment of the inventive concept is not limited thereto. For example, in an embodiment, the light-emitting layers EML-R, EML-G, and EML-B of the first to third light-emitting elements ED-1, ED-2, and ED-3 may have thicknesses different from each other.

In the light-emitting element ED according to an embodiment, the electron transport region ETR is provided on the light-emitting layers EML-R, EML-G, and EML-B. The electron transport region ETR may include at least one of an electron transport layer and an electron injection layer, but an embodiment is not limited thereto.

The electron transport region ETR may have a single layer composed of a single material, a single layer composed of a plurality of different materials, or a plurality of layers composed of a plurality of different materials. For example, the electron transport region ETR may have a structure of a single layer composed of the electron injection layer or the electron transport layer, or a structure of a single layer composed of an electron injection material and an electron transport material. For example, the electron transport region ETR may have a thickness of about 20 nm to about 150 nm.

The electron transport region ETR may be formed using various methods such as a vacuum deposition method, a spin coating method, a casting method, an LB (Langmuir-Blodgett) method, an inkjet printing method, a laser printing method, a laser induced thermal imaging (LITI) method, or the like.

In an embodiment, the electron transport region ETR may include an anthracene-based compound, Alq3 (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, DPEPO (bis[2-(diphenylphosphino)phenyl]etheroxide), 2-(4-(N-phenylbenzimidazolyl-1-ylphenyl)-9,10-dinaphthylanthracene, TPBi (1,3,5-tri(1-phenyl-1H-benzo[d]imidazol-2-yl)phenyl), or a mixture thereof. In another embodiment, the electron transport region ETR may include: a metal halide such as LiF, NaCl, CsF, RbCl, or RbI; a lanthanide metal such as Yb; or a metal oxide such as Li₂O, BaO, LiQ (Lithium quinolate), or the like.

The second electrode EL2 may be a common electrode. The second electrode EL2 may be an anode or a cathode, but an embodiment is not limited thereto. For example, in a case that the first electrode EL1 is an anode, the second electrode EL2 may be a cathode, and in a case that the first electrode EL1 is a cathode, the second electrode EL2 may be an anode.

The second electrode EL2 may be a transmissive electrode, a semi-transmissive electrode, or a reflective electrode. In a case that the second electrode EL2 is a transmissive electrode, the second electrode EL2 may be formed of a transparent conductive oxide, for example, indium-tin oxide (ITO), indium-zinc oxide (IZO), zinc oxide (ZnO), indium-tin-zinc oxide (ITZO), or the like.

In a case that the second electrode EL2 is a semi-transmissive electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In an embodiment, the second electrode EL2 may have a multilayer structure including a reflective film or a semi-transmissive film formed of the above-described materials, and transparent conductive film formed of indium-tin oxide (ITO), indium-zinc oxide (IZO), zinc oxide (ZnO), indium-tin-zinc oxide (ITZO), or the like. For example, the second electrode EL2 may include a metal material as described above, a combination of at least two of the metal materials as described above, an oxide of a metal material as described above, or the like.

The encapsulation layer TFE may be disposed on the light-emitting elements ED-1, ED-2, and ED-3 to cover the light-emitting elements ED-1, ED-2, and ED-3. The encapsulation layer TFE may be a single layer or may be formed by stacking a plurality of layers. The encapsulation layer TFE may be a thin-film encapsulation layer. The encapsulation layer TFE may protect the light-emitting elements ED-1, ED-2, and ED-3. The thin-film encapsulation layer TFE may cover the upper surface of the second electrode EL2 disposed in the opening OH, and may fill the opening OH.

The display device DD according to an embodiment may include an optical layer PP. The optical layer PP may be disposed on the display panel DP. The optical layer PP may include a color filter layer CFL and an optical structure layer BL disposed on the color filter layer CFL.

The optical structure layer BL may block external light supplied from the exterior of the display device DD to the display panel DP. The optical structure layer BL may be a reflection reduction layer that reduces reflectance of external light. For example, the optical structure layer BL may include a polarizing film including a retarder and/or a polarizer, multi-layered reflective layers that destructively interferes reflective light, or color filters disposed corresponding to a pixel arrangement and a color of light emitted by a pixel in the display panel DP. In a case that the optical structure layer BL includes the color filters, the color filters may be arranged in consideration of the color of light emitted by pixels included in the display panel DP. In addition, in an embodiment, the optical structure layer BL may be omitted.

The color filter layer CFL may include first to third color filters CF—R, CF-G, and CF—B, and a light-blocking portion BM in which light-blocking openings OH-BM are defined.

The first to third color filters CF—R, CF-G, and CF—B may each include a polymer photosensitive resin and a colorant. The first to third color filters CF—R, CF-G, and CF—B may be respectively disposed corresponding to the first to third light-emitting regions PXA-R, PXA-G, and PXA-B. The first to third color filters CF—R, CF-G, and CF—B may be respectively disposed in the light-blocking openings OH-BM defined by the light-blocking portion BM to be distinguished from each other.

The color filter layer CFL includes a first color filter CF—R corresponding to the first light-emitting region PXA-R, and a second color filter CF-G corresponding to the second light-emitting region PXA-G. The color filter layer CFL may include the first color filter CF—R that transmits first light, and the second color filter CF-G that transmits second light. The first color filter CF—R may transmit red color light, and the second color filter CF-G may transmit green color light. In an embodiment, the first color filter CF—R may be a red color filter, and the second color filter CF-G may be a green color filter. The first color filter CF—R may include a red colorant, and the second color filter CF-G may include a green colorant. The first color filter CF—R may include a red pigment or red dye, and the second color filter CF-G may include a green pigment or green dye. For example, the first color filter CF—R and the second color filter CF-G may be yellow color filters. The first color filter CF—R and the second color filter CF-G may be integrally provided without being distinguished from each other.

The color filter layer CFL includes a third color filter CF—B corresponding to the third light-emitting region PXA-B. The third color filter CF—B includes a colorant and scattering particles SN. The third color filter CF—B may include a blue colorant and the scattering particles SN of a metal oxide.

The third color filter CF—B may include a scattering portion SP and a filter portion FP sequentially stacked. The third color filter CF—B may include the scattering portion SP and the filter portion FP directly disposed on the scattering portion SP. The third color filter CF—B may be composed of the scattering portion SP and the filter portion FP sequentially stacked in the light-blocking opening OH-BM.

The third color filter CF—B may include the scattering portion SP including the scattering particles SN. The scattering portion SP may include the scattering particles SN that scatter light in a specific range, without including a separate colorant (for example, a pigment or dye). For example, since the scattering portion SP includes the scattering particles SN, the scattering portion SP may at least partially scatter third light generated by the third light-emitting element ED-3. The scattering particles SN may include a metal oxide. The scattering particles SN may include at least one of zinc oxide, titanium oxide, and silicon oxide. For example, the scattering particles SN may include titanium dioxide (TiO₂). However, a material of the scattering particles SN is not limited thereto, and the scattering particles SN may include various types of materials capable of scattering light. The third color filter CF—B according to an embodiment may include the scattering particles SN, and thus may scatter and emit the third light, thereby improving light-emitting characteristics and color purity of the display device DD. Although the display device DD according to an embodiment include an organic light-emitting material instead of a quantum dot in the third light-emitting element ED-3, the display device DD according to an embodiment may include the scattering particles SN in the third color filter CF—B, thereby improving the light-emitting characteristics and the color purity of the display device DD. In addition, as the third color filter CF—B may include the scattering particles SN, the third light may be scattered, thereby improving light-emitting characteristics of the third light not only in a direction parallel to the third direction DR3 but also in a direction oblique with respect to the third direction DR3. That is, the third color filter CF—B may include the scattering particles SN, thereby improving WAD characteristics with respect to blue light which is the third light.

The scattering portion SP may further include a polymer photosensitive resin. The scattering portion SP may include the polymer photosensitive resin, and the scattering particles SN dispersed in the polymer photosensitive resin. The scattering portion SP may be formed of a transparent photosensitive resin, and the scattering particles SN dispersed in the transparent photosensitive resin. The polymer photosensitive resin included in the scattering portion SP may include a material the same as, or as needed, different from the polymer photosensitive resin included in the filter portion FP.

The third color filter CF—B may include the filter portion FP including a colorant. The third color filter CF—B may include the filter portion FP that transmits the third light. The filter portion FP may be disposed on the scattering portion SP. The filter portion FP may transmit blue light. In an embodiment, the filter portion FP may be a blue color filter. The filter portion FP may include a blue colorant. For example, the filter portion FP may include a blue pigment or blue dye. However, an embodiment is not limited thereto, and the filter portion FP may not include a pigment or dye as needed. The filter portion FP may include a polymer photosensitive resin, and may not include a pigment or dye. The filter portion FP may be transparent. The filter portion FP may be formed of a transparent photosensitive resin.

The color filter layer CFL may include the light-blocking portion BM that sets boundaries of adjacent first to third color filters CF—R, CF-G, and CF—B. The light-blocking portion BM may be disposed corresponding to the non-light-emitting region NPXA disposed between the light-emitting regions PXA-R, PXA-G, and PXA-B. The light-blocking portion BM may have a function of preventing a light leakage phenomenon, and color mixing. The light-blocking portion BM may be formed of a blue color filter, or may be formed including an organic light-blocking material or an inorganic light-blocking material including a black pigment or black dye. The light-blocking portion BM may be a black matrix.

The color filter layer CFL may further include a buffer layer. For example, the buffer layer) may be a protective layer that protects the color filters CF—R, CF-G, and CF—B. The buffer layer may be an inorganic material layer including at least one inorganic material among silicon nitride, silicon oxide, and silicon oxynitride. The buffer layer may be composed of a single layer or a multiple layer as needed.

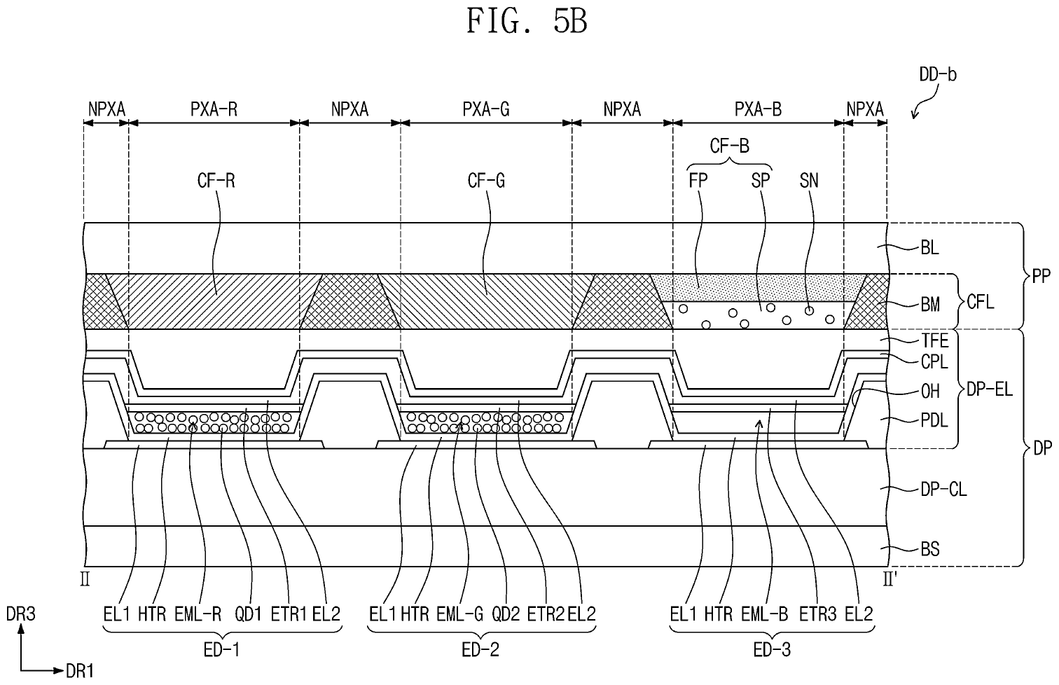

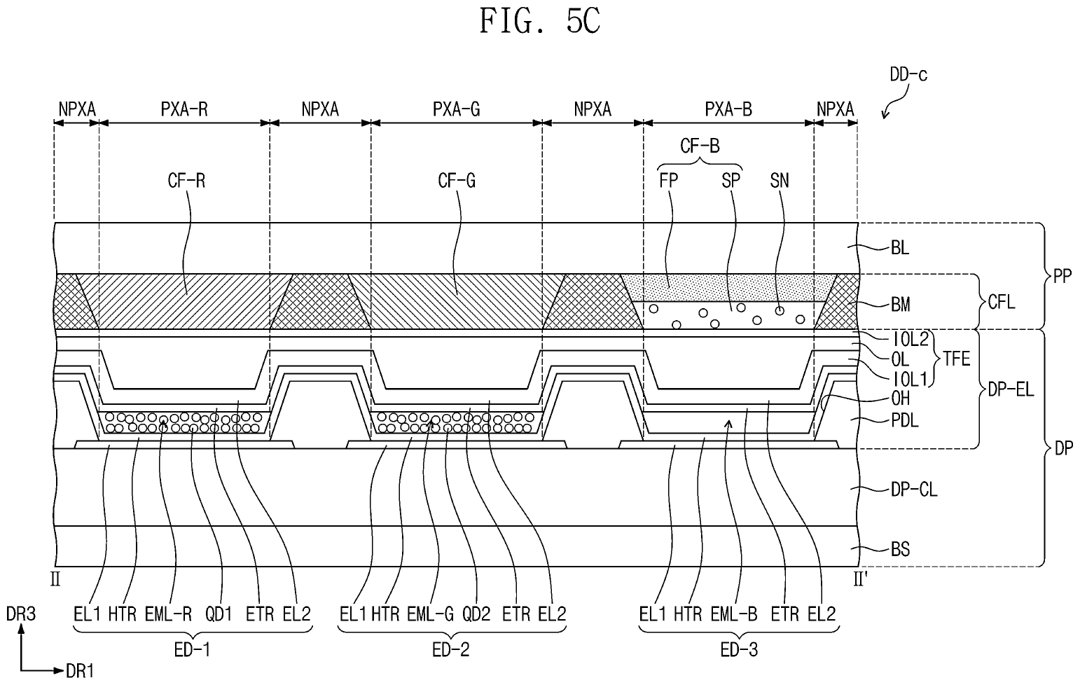

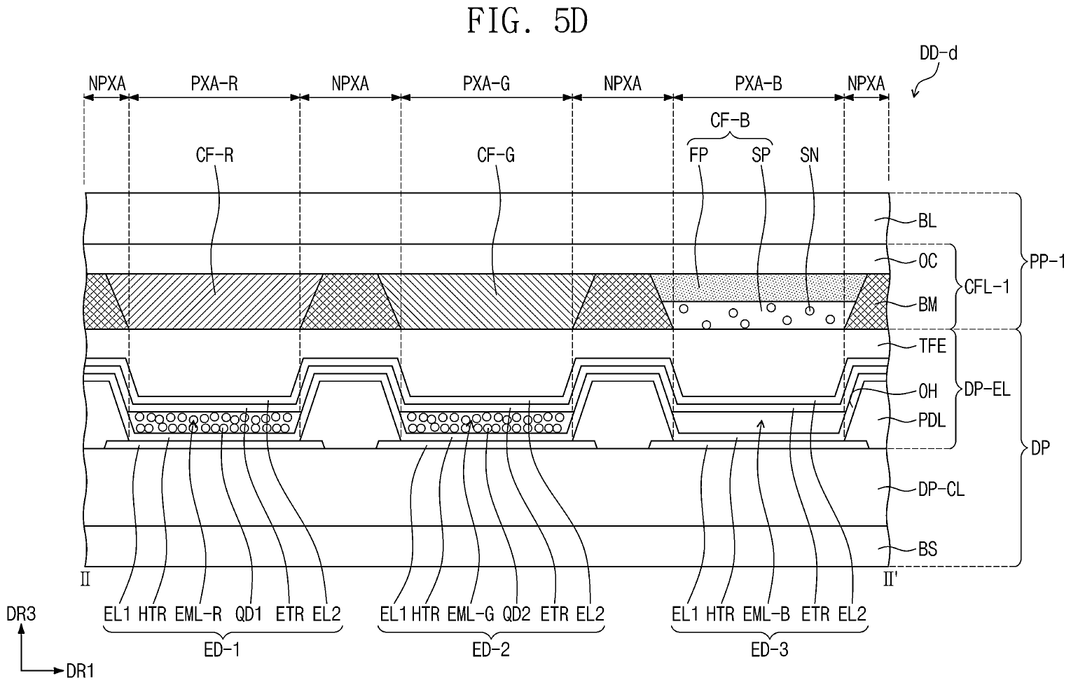

FIGS. 5A to 5D are cross-sectional views of display devices DD-a, DD-b, DD-c, and DD-d according to another embodiment, respectively. FIGS. 5A to 5D each illustrate a portion corresponding to line II-II′ in FIG. 3, and respectively illustrate the display devices DD-a, DD-b, DD-c, and DD-d according to another embodiment different from the display device DD illustrated in FIG. 4.

Referring to FIG. 5A, a third light-emitting element ED-3a may include a plurality of light-emitting layers EML-B1 and EML-B2. That is, the third light-emitting element ED-3a may be a light-emitting element having a tandem structure. For example, the third light-emitting element ED-3a may include a (3-1)-th light-emitting layer EML-B1 disposed on the first electrode EL1, a charge generation layer OG disposed on the (3-1)-th light-emitting layer EML-B1, and a (3-2)-th light-emitting layer EML-B2 disposed on the charge generation layer OG.

In a case that a voltage is applied, the charge generation layer OG may generate charges (electrons and holes) by forming a coordination complex through an oxidation-reduction reaction. A charge generation unit CGL may increase efficiency of current generated by each of adjacent light-emitting layers EML-B1 and EML-B2, and may serve to control balance of the charges between the adjacent light-emitting layers EML-B1 and EML-B2. The charge generation layer may include an N-type arylamine-based material, or a P-type metal oxide. For example, the charge generation layers may include a charge generation compound formed of an arylamine-based organic compound, a carbazole-based compound, metal, a metal oxide, a metal carbide, a metal fluoride, or a mixture thereof.

The charge generation layer OG may include a P-type charge generation layer and an N-type charge generation layer. The charge generation layer OG may have a stack structure in which the P-type charge generation layer and the N-type charge generation layer are bonded with each other. The N-type charge generation layer may be a charge generation layer that supplies electrons to light-emitting layers EML-B1 and EML-B2 adjacent thereto. The N-type charge generation layer may include an N-type dopant. The N-type charge generation layer may be a layer in which the N-type dopant is doped to a base material. The P-type charge generation layer may be a charge generation layer that supplies holes to the light-emitting layers EML-B1 and EML-B2 adjacent thereto. The P-type charge generation layer may include a P-type dopant. The P-type charge generation layer may be a layer in which the P-type dopant is doped to the base material. A buffer layer may be further disposed between the N-type charge generation layer and the P-type charge generation layer.

Unlike what is illustrated in FIG. 5A, the third light-emitting element ED-3a may include n light-emitting layers, and (n−1) charge generation layers disposed between adjacent light-emitting layers. In the specification, n may be an integer equal to or greater than 3.

Referring to FIG. 5B, the first to third light-emitting elements ED-1, ED-2, and ED-3 may respectively include first to third electron transport regions ETR1, ETR2, and ETR3, and the first to third electron transport regions ETR1, ETR2, and ETR3 may be provided as pattern layers. In the present specification, “a common layer” may mean a layer commonly provided to the entire first to third light-emitting elements ED-1, ED-2, and ED-3 and substantially constituting one configuration, and “a pattern layer” may mean a layer provided spaced apart by being patterned in the opening OH defined in the pixel-defining film PDL. The first to third electron transport regions ETR1, ETR2, and ETR3 may be respectively disposed, as the pattern layers, on the light-emitting layers EML-1, EML-2, and EML-3 so as to respectively correspond to the first to third light-emitting regions PXA-R, PXA-G, and PXA-B.

The first electron transport region ETR1 and the second electron transport region ETR2 may each include an inorganic material. For example, the first electron transport region ETR1 and the second electron transport region ETR2 may each independently include: a metal halide such as LiF, NaCl, CsF, RbCl, or RbI; a lanthanide metal such as Yb; a metal oxide such as Li₂O, BaO, LiQ (Lithium quinolate), or the like.

The third electron transport region ETR3 may include an organic material. For example, the third electron transport region ETR3 may include an anthracene-based compound, Alq3 (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, DPEPO (bis[2-(diphenylphosphino)phenyl]etheroxide), 2-(4-(N-phenylbenzimidazolyl-1-ylphenyl)-9,10-dinaphthylanthracene, TPBi (1,3,5-tri(1-phenyl-1H-benzo[d]imidazol-2-yl)phenyl), or a mixture thereof.

In an embodiment, the first to third light-emitting elements ED-1, ED-2, and ED-3 may further include a capping layer CPL disposed on the second electrode EL2. The capping layer CPL may be an organic layer or an inorganic layer. For example, in a case that the capping layer CPL includes an inorganic material, the inorganic material may include an alkali metal compound such as LiF, an alkaline earth metal compound such as MgF₂, SiON, SiNₓ, SiO_{y}, or the like. For example, in a case that the capping layer CPL includes an organic material, the organic material may include α-NPD, NPB, TPD, m-MTDATA, Alq3, CuPc, TPD15 (N4,N4,N4′,N4′-tetra(biphenyl-4-yl)biphenyl-4,4′-diamine), TCTA (4,4′,4″-tris(carbazol-9-yl)triphenylamine), or the like, or may include an epoxy resin, or an acrylate such as methacrylate. The capping layer CPL may have a refractive index equal to or greater than about 1.6. For example, the capping layer CPL may have a refractive index equal to or greater than about 1.6, with respect to light in a wavelength range of about 550 nm to about 600 nm.

Referring to FIG. 5C, an encapsulation layer TFE may have a multi-layered structure in which an inorganic layer/an organic layer are repeated. In an embodiment, the encapsulation layer TFE may include a first inorganic encapsulation layer IOL1/an organic encapsulation layer OL/a second inorganic encapsulation layer IOL2. The first and second inorganic encapsulation layers IOL1/IOL2 may protect the light-emitting elements ED-1, ED-2, and ED-3 from external moisture, and the organic encapsulation layer OL may prevent a dent defect of the light-emitting elements ED-1, ED-2, and ED-3 by foreign matters introduced during a manufacturing process. The first and second inorganic encapsulation layers IOL1/IOL2 protects a display element layer DP-EL from moisture/oxygen, and the organic encapsulation layer OL protects the display element layer DP-EL from the foreign matters such as dust particles. The first and second inorganic encapsulation layers IOL1/IOL2 may each include silicon nitride, silicon oxynitride, silicon oxide, titanium oxide, aluminum oxide, or the like, but embodiments are not limited thereto. The organic encapsulation layer OL may include an acrylic compound, an epoxy-based compound, or the like. The organic encapsulation layer OL may include a photopolymerizable organic material, but embodiments are not limited thereto. In FIG. 5C, the display panel DP may further include, on the encapsulation layer TFE, a refractive index-controlling layer for improving light-emitting efficiency.

Referring to FIG. 5D, an optical layer PP-1 may include a color filter layer CFL-1, and the color filter layer CFL-1 may further include an overcoat layer OC. The overcoat layer OC may be disposed on the first to third color filters CF—R, CF-G, and CF—B. The overcoat layer OC may be an organic layer that protects the first to third color filters CF—R, CF-G, and CF—B. The overcoat layer OC may cover the first to third color filters CF—R, CF-G, and CF—B, and may planarize upper surfaces of the first to third color filters CF—R, CF-G, and CF—B. In an embodiment, a glass substrate for protecting the overcoat layer OC may be further disposed on the overcoat layer OC, and an adhesive layer may be disposed between the overcoat layer OC and the glass substrate. The overcoat layer OC may include an optically curable organic material or a thermally curable organic material. However, a material included in the overcoat layer OC is not limited thereto, and the overcoat layer OC may include an inorganic material.

A display device according to an embodiment may include a light-emitting layer including an organic light-emitting material, and a color filter including scattering particles, thereby improving light-emitting characteristics and a lifespan of a light-emitting element.

In the above, description has been made with reference to embodiments described hereinabove, but those skilled in the art or those of ordinary skill in the relevant technical field may understand that various modifications and changes may be made to the embodiments within the scope not departing from the spirit and the technology scope of the disclosure described in the claims to be described later. Therefore, the technical scope of the disclosure is not limited to the contents described in the detailed description of the specification, but should be determined by the claims.

What is claimed is:

1. A display device comprising:
a base layer;
a circuit layer disposed on the base layer;
a display element layer disposed on the circuit layer, and including a light-emitting element; and
an optical layer disposed on the display element layer, wherein
the light-emitting element includes:
a first light-emitting element overlapping a first light-emitting region, and including a first light-emitting layer;
a second light-emitting element overlapping a second light-emitting region, and including a second light-emitting layer; and
a third light-emitting element overlapping a third light-emitting region, and including a third light-emitting layer,
the first light-emitting layer and the second light-emitting layer respectively include a first quantum dot and a second quantum dot,
the third light-emitting layer includes an organic light-emitting material, and
the optical layer includes:
a first color filter overlapping the first light-emitting region;
a second color filter overlapping the second light-emitting region; and
a third color filter overlapping the third light-emitting region, and including scattering particles.

2. The display device of claim 1, wherein the scattering particles comprise at least one of zinc oxide, titanium oxide, and silicon oxide.

3. The display device of claim 1, wherein the third color filter comprises:
a scattering portion disposed on the display element layer, and including the scattering particles; and
a filter portion disposed on the scattering portion, and including a colorant.

4. The display device of claim 3, wherein the scattering portion further comprises a polymer photosensitive resin, and the scattering particles are distributed in the polymer photosensitive resin.

5. The display device of claim 3, wherein the display element layer further comprises an encapsulation layer covering the light-emitting element, and the scattering portion is in contact with the encapsulation layer.

6. The display device of claim 3, wherein the filter portion is directly disposed on the scattering portion.

7. The display device of claim 3, wherein the scattering portion has a thickness in a range of about 1 μm to about 4 μm.

8. The display device of claim 3, wherein
the first color filter comprises a red pigment or dye,
the second color filter comprises a green pigment or dye, and
the colorant included in the filter portion comprises a blue pigment or dye.

9. The display device of claim 1, wherein the optical layer further comprises:
light-blocking portions respectively disposed between the first color filter, the second color filter, and the third color filter.

10. The display device of claim 1, wherein the optical layer further comprises:
an overcoat layer disposed on the first to third color filters.

11. The display device of claim 1, wherein
the first to third light-emitting elements respectively generate first to third light, and
the third light is blue color light having a central wavelength of in a range about 420 nm to about 480 nm.

12. The display device of claim 1, wherein
the first light-emitting layer comprises a first host and a first dopant,
the second light-emitting layer comprises a second host and a second dopant,
the first dopant comprises the first quantum dot, and
the second dopant comprises the second quantum dot.

13. The display device of claim 1, wherein
the third light-emitting layer comprises a third host and a third dopant, and
the third host and the third dopant each comprises the organic light-emitting material.

14. The display device of claim 13, wherein the third dopant comprises a delayed fluorescent dopant.

15. The display device of claim 1, wherein
the light-emitting element comprises:
a first electrode;
a light-emitting layer disposed on the first electrode; and
a second electrode disposed on the light-emitting layer, and
the light-emitting layer comprises the first light-emitting layer, the second light-emitting layer, and the third light-emitting layer.

16. The display device of claim 15, wherein the light-emitting element further comprises a capping layer disposed on the second electrode.

17. The display device of claim 15, wherein
the first light-emitting element further comprises a first electron transport region disposed on the first light-emitting layer,
the second light-emitting element further comprises a second electron transport region disposed on the second light-emitting layer, and
the first electron transport region and the second electron transport region each comprise an inorganic material.

18. The display device of claim 15, wherein
the third light-emitting element further comprises a third electron transport region disposed on the third light-emitting layer, and
the third electron transport region comprises an organic material.

19. The display device of claim 15, wherein
the third light-emitting layer comprises:
a (3-1)-th light-emitting layer disposed on the first electrode; and
a (3-2)-th light-emitting layer disposed on the (3-1)-th light-emitting layer, and
the third light-emitting element further comprises a charge generation layer disposed between the (3-1)-th light-emitting layer and the (3-2)-th light-emitting layer.

20. A display device comprising:
a base layer;
a circuit layer disposed on the base layer;
a display element layer disposed on the circuit layer, and including a light-emitting element; and
an optical layer disposed on the display element layer, wherein
the light-emitting element includes an organic light-emitting material, and
the optical layer includes:
a scattering portion including titanium dioxide (TiO₂); and
a filter portion directly disposed on the scattering portion, and including a pigment or dye.
